(19) United States
(12) Patent Application Publication
(10) Pub. No.: US 2005/0276426 A1
(43) Pub. Date: Dec. 15, 2005

(54) Information processing apparatus, volume control method, recording medium, and program

(76) Inventors: Kenichi Ono, Tokyo (JP); Kenji Takagi, Kanagawa (JP); Yuichiro Sasabe, Kanagawa (JP); Keisuke Koide, Tokyo (JP); Kiyoshi Hasegawa, Tokyo (JP)

Correspondence Address: William S. Frommer, Esq.;FROMMER LAWRENCE & HAUG LLP, 745 Fifth Avenue, New York, NY, 10151, US

(21) Appl. No.: 11/116,929

(22) Filed: Apr. 28, 2005

(30) Foreign Application Priority Data
Apr. 30, 2004 (JP) 2004-136800

(51) Int. Cl. H03G 3/00; G06F 17/00

(52) U.S. Cl. 381/104; 381/107; 700/94

(57) ABSTRACT

An information processing apparatus is connected to a sound output device for outputting sound based on digital audio data. The information processing apparatus includes the following elements. A first receiver receives setting data for setting a volume of sound output from the sound output device, the volume being set by a function implemented by a first computer executing a first program. A second receiver receives a setting signal for setting a volume of sound output from the sound output device, the volume being supplied from a setting unit provided for the sound output device. A calculator calculates first volume control data that controls the volume of sound output from the sound output device based on the setting data and the setting signal, the volume being controlled by a second computer executing a second program. A first output unit outputs the first volume control data to the sound output device.

### CROSS REFERENCES TO RELATED APPLICATIONS

The present invention contains subject matter related to Japanese Patent Application JP 2004-136800 filed in the Japanese Patent Office on Apr. 30, 2004, the entire contents of which are incorporated herein by reference.

### BACKGROUND OF THE INVENTION

1. Field of the Invention

The present invention relates to information processing apparatuses, volume control methods, recording media, and programs. More particularly, the invention relates to an information processing apparatus, a volume control method, a recording medium, and a program in which the output volume of a digital volume output device can be controlled.

2. Description of the Related Art

Port replicators, which are connected to mobile personal computers to increase the number of ports through which data can be input and output, are widely used. Some port replicators include, not only, a port through which analog signals or digital data can be input and output, but also a loudspeaker and an amplifier for driving the loudspeaker.

Port replicators provided with loudspeakers and amplifiers that can play back higher-quality sound, for example, audio data played back by a compact disc (CD) drive or a digital versatile disc (DVD) drive or audio data downloaded from web sites on the Internet, are commercially available. Some port replicators provided with digital amplifiers to directly input digital audio data from personal computers so that higher quality audio data can be played back with lower power consumption are also commercially available. Such port replicators are used as sound output devices.

FIG. 1 is a block diagram illustrating an example of the configuration of part of a personal computer 1 and a typical type of digital sound output device 2, which serves as a port replicator.

The sound output device 2 is connected to a digital sound output terminal, such as an optical output terminal, of the personal computer 1. The personal computer 1 outputs pulse code modulation (PCM) audio data to the sound output device 2.

The personal computer 1 includes a central processing unit (CPU) 11, an audio codec 12, an analog amplifier 13, a built-in loudspeaker 14, and a controller 15.

The CPU 11 executes a predetermined program to control the individual elements of the personal computer 1. The CPU 11 also receives, for example, audio code number 3 (AC3) digital audio data, from a CD drive or a DVD drive (not shown), and supplies the audio data to the audio codec 12. Additionally, when a user sets the volume of the built-in loudspeaker 14, the CPU 11 supplies a volume signal indicating the volume set by the user to the audio codec 12 by using the function of a program executed by the CPU 11.

The audio codec 12 decodes the audio data supplied from the CPU 11 and converts the decoded audio data into an analog audio signal based on the volume signal supplied from the CPU 11. The audio codec 12 then supplies the analog audio signal to the analog amplifier 13.

The audio codec 12 also decodes audio data supplied from the CPU 11 and encodes it to PCM audio data. The audio codec 12 outputs the PCM audio data to a digital amplifier 23 of the sound output device 2. The signal level of the PCM audio data output from the audio codec 12 is determined by the signal level of the audio data supplied from the CPU 11 without being influenced by the volume signal based on the volume set by the user.

The analog amplifier 13 amplifies the analog audio signal supplied from the audio codec 12, and outputs the amplified signal to the built-in loudspeaker 14. The built-in loudspeaker 14 outputs sound in accordance with the received audio signal.

The controller 15 is formed of, for example, a CPU, which is operated independently of the CPU 11. The controller 15 controls the input from a keyboard (not shown), and supplies the key status of the keyboard to the CPU 11 if necessary. The controller 15 also monitors, for example, the remaining amount of batteries (not shown) or the temperature of the personal computer 1, and controls the power consumption of the power source of the individual elements of the personal computer 1.

The sound output device 2 includes a volume switch 21, a controller 22, the digital amplifier 23, and a loudspeaker 24.

The volume switch 21 is provided with, for example, a volume knob. When a user operates the volume knob, the volume switch 21 supplies a volume signal indicating the volume level in accordance with the position of the volume knob to the controller 22.

The controller 22 is formed of, for example, a CPU, and calculates the gain to be supplied to the digital amplifier 23 based on the volume signal supplied from the volume switch 21, and supplies data indicating the calculated gain to the digital amplifier 23.

The digital amplifier 23 drives the loudspeaker 24 with the gain represented by the data supplied from the controller 22 based on the PCM audio data input from the audio codec 12 to output sound.

As stated above, the sound volume output from the built-in loudspeaker 14 of the personal computer 1 is set by the personal computer 1 by using the function of the program executed by the CPU 11. In contrast, the sound volume output from the loudspeaker 24 of the sound output device 2 is set by the sound output device 2 by operating the volume switch 21.

The following sound mute device is disclosed in, for example, Japanese Unexamined Patent Application Publication No. 7-264500. In this sound mute device, in the television-broadcasting reception mode, when a video signal has no sound level or a weak electric field, a sound mute function is turned ON. In the external video input mode, the sound mute function is turned OFF.

The following sound control device is disclosed in, for example, Japanese Unexamined Patent Application Publication No. 2003-209764. In a multi-function device containing a DVD player, a television set, and a video cassette recorder (VCR) in the same housing, the sound control device controls sound to be output at a constant volume level regardless of the sound output mode.

### SUMMARY OF THE INVENTION

In the personal computer 1 and the sound output device 2 shown in FIG. 1, however, it is difficult to set the volume of sound output from the loudspeaker 24 of the sound output device 2 by the personal computer 1. In order to allow the personal computer 1 to set the volume of the sound output from the loudspeaker 24, it is necessary to provide a digital amplifier for the personal computer 1.

The inventions of the above-described publications do not disclose that the volume of an external sound output device connected to the sound mute device or the sound control device is controlled.

It is thus desirable to allow an information processing apparatus to control the output volume of a digital sound output device connected to the information processing apparatus.

According to an embodiment of the present invention, there is provided an information processing apparatus to which a sound output device for outputting sound based on digital audio data is connected. The information processing apparatus includes the following elements. First receiving means receives setting data for setting a volume of sound output from the sound output device, the volume being set by a function implemented by a first computer executing a first program. Second receiving means receives a setting signal for setting a volume of sound output from the sound output device, the volume being supplied from setting means provided for the sound output device. Calculation means calculates first volume control data that controls the volume of sound output from the sound output device based on the setting data and the setting signal, the volume being controlled by a second computer executing a second program. First output means outputs the first volume control data to the sound output device.

The calculation means may store in advance first intermediate data corresponding to one of the setting data and the setting signal and convert the one of the setting data and the setting signal into the first intermediate data, thereby calculating the first volume control data based on the other one of the setting data and the setting signal and the first intermediate data.

The first volume control data may include second volume control data and third volume control data. The calculation means may store in advance the plurality of different second volume control data to which a plurality of different second intermediate data are assigned, the one of the setting data and the setting signal may be converted into the first intermediate data, the other one of the setting data and the setting signal and the first intermediate data may be added, some bits of a resulting added value may be used as the second intermediate data, the remaining bits of the added value may be used as the third volume control data, and the second intermediate data may be converted into the second volume control data to which the second intermediate data is assigned, thereby calculating the first volume control data.

The second receiving means may receive a stop instruction signal indicating an instruction to stop outputting the sound from the sound output device. The information processing apparatus may further include second output means for outputting, in response to the stop instruction signal, a mute signal indicating an instruction to stop outputting the sound from the sound output device to the sound output device and also for outputting mute changing information indicating a change in the output of the mute signal to the first computer executing the first program.

According to another embodiment of the present invention, there is provided a volume control method for an information processing apparatus to which a sound output device for outputting sound based on digital audio data is connected. The volume control method includes the steps of: performing a first receiving operation for receiving setting data for setting a volume of sound output from the sound output device, the volume being set by a function implemented by a first computer executing a first program; performing a second receiving operation for receiving a setting signal for setting a volume of sound output from the sound output device, the volume being supplied from setting means provided for the sound output device; calculating volume control data that controls the volume of sound output from the sound output device based on the setting data and the setting signal, the volume being controlled by a second computer executing a second program; and outputting the volume control data to the sound output device.

According to another embodiment of the present invention, there is provided a recording medium recording therein a computer-readable program, the computer-readable program being used for controlling a volume of a second computer of an information processing apparatus. A sound output device for outputting sound based on digital audio data is connected to the information processing apparatus. The information processing apparatus includes receiving means for receiving setting data for setting a volume of sound output from the sound output device, the volume being set by a function implemented by a first computer executing a volume setting program. The computer-readable program includes the steps of: receiving a setting signal for setting a volume of sound output from the sound output device, the volume being supplied from setting means provided for the sound output device; calculating volume control data that controls the volume of sound output from the sound output device based on the setting data and the setting signal; and outputting the volume control data to the sound output device.

According to another embodiment of the present invention, there is provided a program allowing a second computer of an information processing apparatus to execute volume control processing for controlling a volume of the information processing apparatus. A sound output device for outputting sound based on digital audio data is connected to the information processing apparatus, the information processing apparatus including receiving means for receiving setting data for setting a volume of sound output from the sound output device, the volume being set by a function implemented by a first computer executing a volume setting program. The program includes the steps of: receiving a setting signal for setting a volume of sound output from the sound output device, the volume being supplied from setting means provided for the sound output device; calculating volume control data that controls the volume of sound output from the sound output device based on the setting data and the setting signal; and outputting the volume control data to the sound output device.

In the information processing apparatus and the volume control method according to an embodiment of the present invention, setting data for setting a volume of sound output from the sound output device for outputting sound based on digital audio data, the volume being set by a function implemented by a first computer executing a first program, is received. A setting signal for setting a volume of sound output from the sound output device, the volume being supplied from setting means provided for the sound output device, is received. Volume control data that controls the volume of sound output from the sound output device is calculated based on the setting data and the setting signal, the volume being controlled by a second computer executing a second program. The volume control data is then output to the sound output device.

In the recording medium and the program according to an embodiment of the present invention, a setting signal for setting a volume of sound output from the sound output device, the volume being supplied from setting means provided for the sound output device, is received. Volume control data that controls the volume of sound output from the sound output device is calculated based on setting data and the setting signal, the setting data being used for setting the volume of sound output from the sound output device, the volume being set by a function implemented by a first computer executing a volume setting program. The volume control data is then output to the sound output device.

As described above, according to the information processing apparatus, the volume control method, the recording medium, and the program, the volume of the output sound of a digital sound output device connected to the information processing apparatus can be controlled without the need to add new components.

### BRIEF DESCRIPTION OF THE DRAWINGS

FIG. 1 is a block diagram illustrating an example of the functional configuration of a known personal computer and a known sound output device;

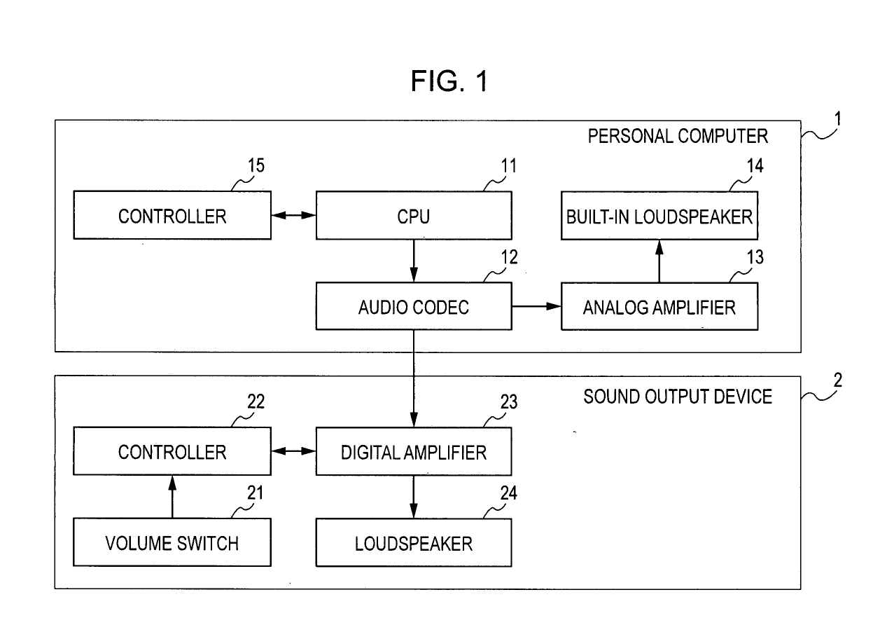

FIG. 2 is a block diagram illustrating the configuration of an information processing system according to an embodiment of the present invention;

FIG. 3 illustrates an example of the functional configuration of a personal computer shown in FIG. 2;

FIG. 4 illustrates an example of the functional configuration of a sound output unit of an A-type port replicator (APR) shown in FIG. 2;

FIG. 5 illustrates an example of the functional configuration of a digital amplifier of the sound output unit shown in FIG. 4;

FIG. 6 illustrates an example of the program structure executed by an information processing system according to an embodiment of the present invention;

FIG. 7 illustrates an example of the functional configuration of an embedded controller;

FIGS. 8 and 9 are flowcharts illustrating switch volume polling processing performed by the embedded controller;

FIG. 10 is a flowchart illustrating system volume informing processing performed by a CPU (utility program);

FIG. 11 is a flowchart illustrating system volume receiving processing performed by the embedded controller;

FIG. 12 is a flowchart illustrating APR volume calculating processing performed by the embedded controller;

FIG. 13 is a flowchart illustrating volume gain calculating processing performed by the embedded controller;

FIG. 14 illustrates an example of the sound pressure level of audio data output from the digital amplifier;

FIG. 15 illustrates another example of the sound pressure level of audio data output from the digital amplifier;

FIG. 16 illustrates the difference of gain calculation methods;

FIG. 17 is a flowchart illustrating APR volume setting processing performed by the embedded controller;

FIG. 18 is a flowchart illustrating initializing processing performed by the embedded controller;

FIG. 19 illustrates a transition of the mute setting condition in an information processing system according to an embodiment of the present invention;

FIG. 20 illustrates the sound output state of an information processing system according to an embodiment of the present invention;

FIGS. 21 and 22 illustrate transitions of the sound output states in an information processing system according to an embodiment of the present invention;

FIG. 23 is a flowchart illustrating mute button polling processing performed by the embedded controller;

FIG. 24 illustrates details of mute condition setting processing in step S207 of FIG. 23;

FIG. 25 is a flowchart illustrating mute setting query processing performed by the CPU (utility program);

FIG. 26 illustrates a dialog when the mute setting is ON;

FIG. 27 illustrates a dialog when the mute setting is OFF;

FIG. 28 is a flowchart illustrating mute setting query response processing performed by the embedded controller;

FIG. 29 is a flowchart illustrating mute setting changing information receiving processing performed by the CPU (utility program);

FIG. 30 is a flowchart illustrating mute setting instruction information receiving processing performed by the embedded controller;

FIG. 31 is a flowchart illustrating unmute setting instruction information receiving processing performed by the embedded controller;

FIG. 32 is a flowchart illustrating port replicator installing/removing detection processing performed by the embedded controller;

FIG. 33 is a flowchart illustrating port replicator installing/removing processing in step S407 of FIG. 32;

FIG. 34 is a flowchart illustrating port-replicator-dedicated application control processing performed by the CPU (utility program);

FIG. 35 is a flowchart illustrating port replicator connecting-state informing processing performed by the embedded controller;

FIG. 36 is a flowchart illustrating audio-unit connecting signal polling processing performed by the embedded controller; and

FIG. 37 is a flowchart illustrating external-unit installing/removing processing in step S507 of FIG. 36.

### DESCRIPTION OF THE PREFERRED EMBODIMENTS

Preferred embodiments of the present invention are described in detail below with reference to the accompanying drawings.

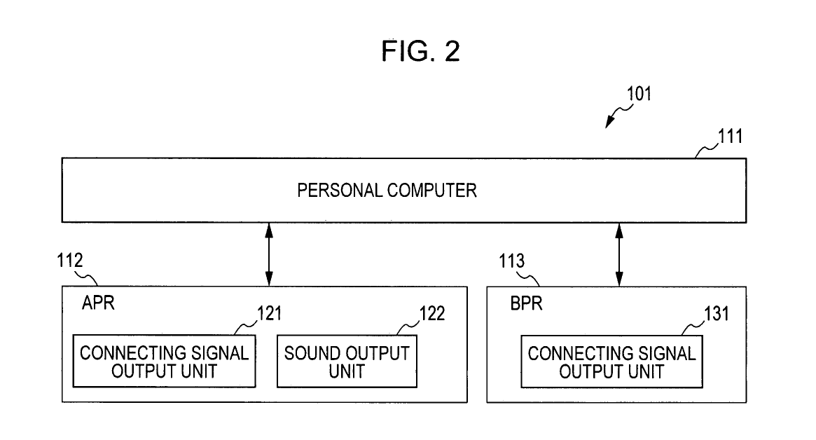

FIG. 2 is a block diagram illustrating the configuration of an information processing system 101 according to an embodiment of the present invention. The information processing system 101 includes a personal computer 111, an A-type port replicator (hereinafter simply referred to as the “APR”) 112, and a B-type port replicator (hereinafter simply referred to as the “BPR”) 113.

The APR 12 and the BPR 13 are used for extending the features of the personal computer 111, and one of the APR 12 and the BPR 13 is connected to the personal computer 111. The APR 12 and the BPR 13 each include connecting terminals, such as a serial port, a parallel port, a PS/2 port, a universal serial bus (USB) port, and an external display output connector, and is connected to an external information processing apparatus according to the necessity.

The APR 12 includes a sound output unit 122 for outputting sound based on digital audio data output from the personal computer 111. On the other hand, the sound output unit 122 is not provided for the BPR 113.

The APR 112 also includes a connecting signal output unit 121, which supplies an APR connecting signal to the personal computer 111 when the APR 112 is connected to the personal computer 111. The APR connecting signal indicates that the port replicator connected to the personal computer 111 is the APR 112. Similarly, the BPR 113 also includes a connecting signal output unit 131, which supplies a BPR connecting signal to the personal computer 111 when the BPR 113 is connected to the personal computer 111. The BPR connecting signal indicates that the port replicator connected to the personal computer 111 is the BPR 113.

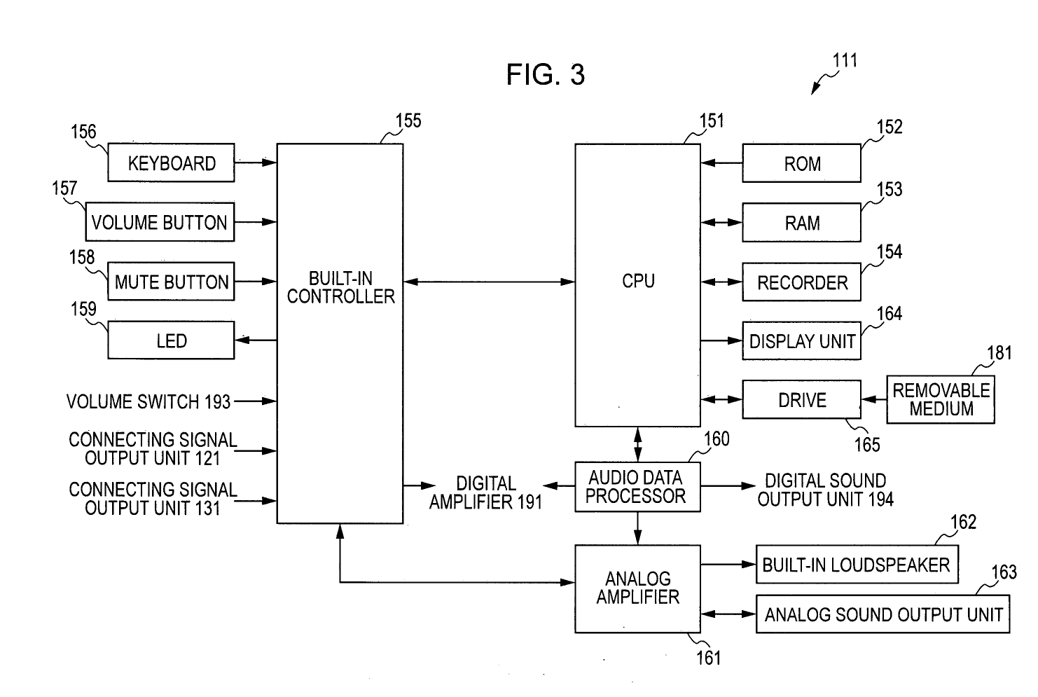

FIG. 3 is a block diagram illustrating the functional configuration of the personal computer 111. The personal computer 111 includes a CPU 151, a read only memory (ROM) 152, a random access memory (RAM) 153, a recorder 154, an embedded controller 155, a keyboard 156, a volume button 157, a mute button 158, a light emitting diode (LED) 159, an audio data processor 160, an analog amplifier 161, a built-in loudspeaker 162, an analog sound output unit 163, a display unit 164, and a drive 165.

The CPU 151 receives an instruction or data input by a user through the keyboard 156 and executes various types of processing based on the input instruction or data in accordance with a program stored in the ROM 152 or a program loaded to the RAM 153 from the recorder 154. The CPU 151 also receives audio data, for example, AC3 audio data or advanced audio coding (AAC) audio data, read from a removable medium 181 by the drive 165 or obtained from an external information processing apparatus connected to a network, such as the Internet, via a communication unit (not shown, and supplies the received audio data to the audio data processor 160. The CPU 151 supplies a volume signal for setting the sound volume to be output from the built-in loudspeaker 162 to the audio data processor 160.

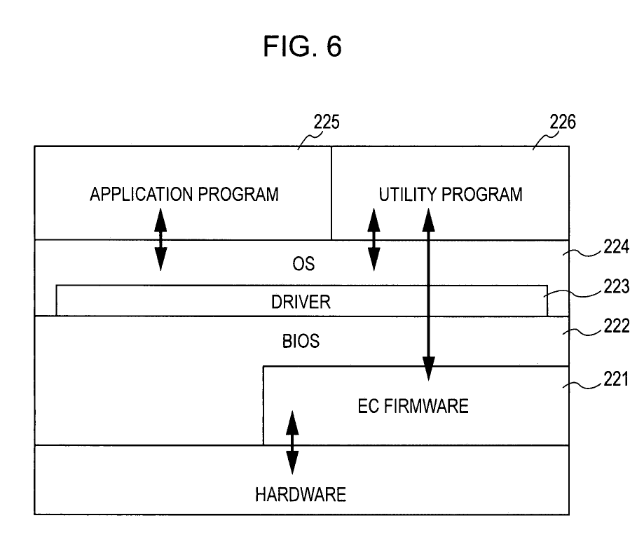

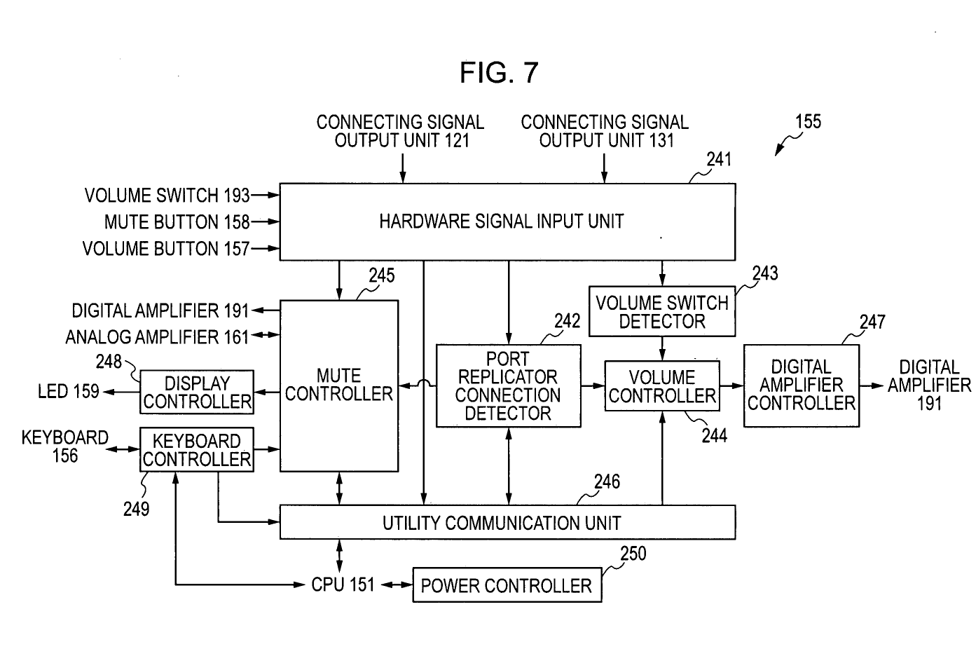

Data and information sent and received between the CPU 151 and the embedded controller 155 are discussed in detail below with reference to FIGS. 6 and 7.

The ROM 152 is connected to the CPU 151 via a bus or a hub (not shown), and basically stores fixed data of the programs and computation parameters used by the CPU 151.

The RAM 153 is connected to the CPU 151 via a bus or a hub (not shown), and basically stores programs used for the execution of the CPU 151 and corresponding variable parameters and data.

The recorder 154 is connected to the CPU 151 via a bus or a hub (not shown). The recorder 154 is formed of, for example, a hard disk, which records or plays back the programs or information executed by the CPU 151.

The embedded controller 155 is a built-in computer, which executes programs other than the programs executed by the CPU 151. The embedded controller 155 includes a general-purpose CPU, and a ROM, a RAM, an electronically erasable and programmable read only memory (EEPROM), or a micro processing unit (MPU), and performs processing independently of the CPU 151.

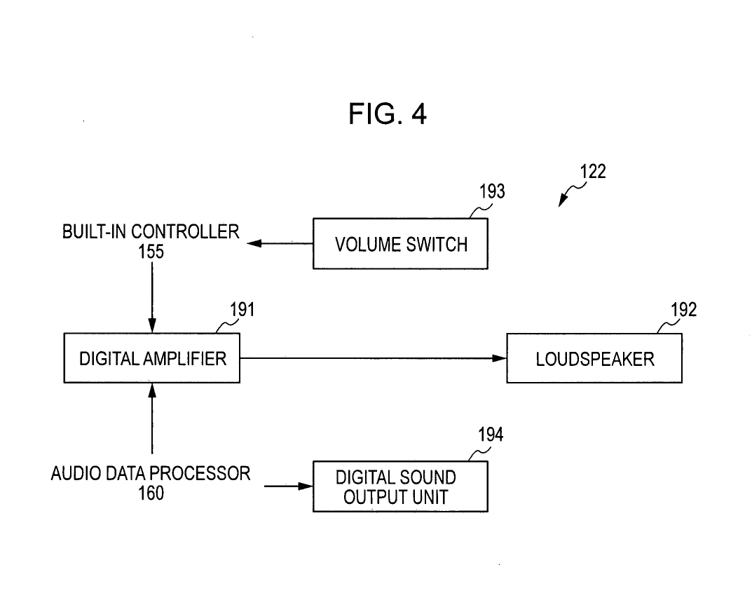

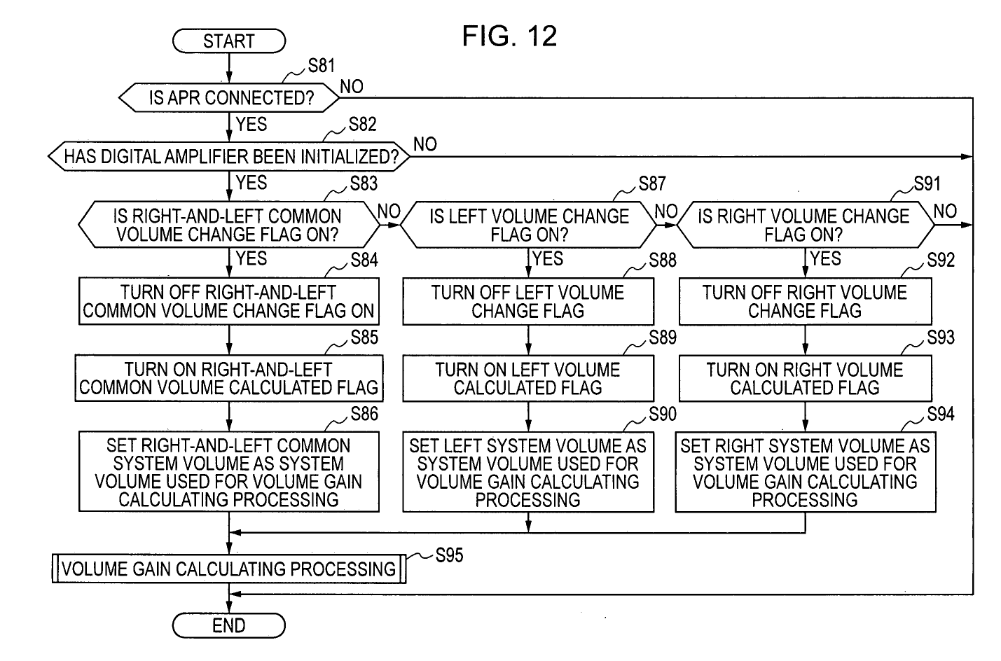

The embedded controller 155 calculates the gain (hereinafter referred to as the “volume gain”) of a digital amplifier 191 (FIG. 4) of the APR 112, which is discussed below with reference to FIGS. 13 through 15, and supplies data indicating the calculated volume gain (hereinafter referred to as the “volume gain data”) to the digital amplifier 191.

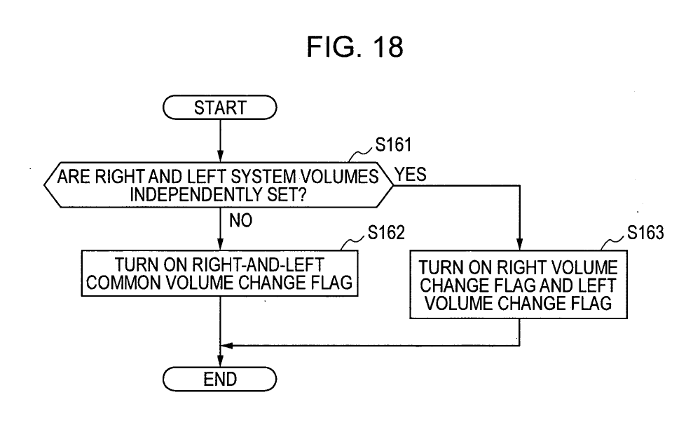

The embedded controller 155 manages a mute setting flag indicating the mute setting of the information processing system 101. The mute setting is to start or stop outputting sound from the information processing system 101. The embedded controller 155 controls the sound output state of the information processing system 101 according to the mute setting, which is discussed in detail below with reference to FIGS. 19 through 22. The embedded controller 155 supplies a mute signal indicating an instruction to stop supplying an audio signal or audio data to the analog amplifier 161 and the digital amplifier 191 (FIG. 4) if necessary.

The embedded controller 155 receives an APR connecting signal from the connecting signal output unit 121 of the APR 112 when the APR 112 is connected to the personal computer 111, and receives a BPR connecting signal from the connecting signal output unit 131 of the BPR 113 when the BPR 113 is connected to the personal computer 111. The embedded controller 155 detects the connecting state of a port replicator connected to the personal computer 111 based on the APR connecting signal or the BPR connecting signal. The embedded controller 155 also controls the LED 159 to be turned ON or OFF.

The embedded controller 155 controls the operation input from the keyboard 156, and supplies the key status of the keyboard 156 to the CPU 151 if necessary. The embedded controller 155 also monitors, for example, the remaining amount of batteries (not shown) or the temperature of the personal computer 111, and controls the power consumption of the power source of the individual elements of the personal computer 111.

The keyboard 156 includes a plurality of switches (keys) to which numbers or characters are assigned. When the user presses a key of the keyboard 156, the keyboard 156 supplies a key signal indicating the corresponding number or character to the embedded controller 155.

The volume button 157 includes two types of buttons, i.e., an up-button and a down-button. When the user presses the up-button, the volume button 157 supplies a volume-increasing signal to the embedded controller 155, and when the user presses the down-button, the volume button 157 supplies a volume-decreasing signal to the embedded controller 155.

The mute button 158 supplies a mute button signal to the embedded controller 155 when the mute button 158 is pressed.

The LED 159 is turned ON or OFF under the control of the embedded controller 155.

The audio data processor 160 includes, for example, a digital signal processor (DSP) and a codec. The audio data processor 160 performs audio processing, such as encoding, decoding, digital-to-analog (D/A) conversion, and analog-to-digital (A/D) conversion, on audio data supplied from the CPU 151. The audio data processor 160 can encode or decode audio data according to the AC3, AAC, or PCM method.

The audio data processor 160 supplies the processed audio data to the CPU 151. The audio data processor 160 also supplies an analog audio signal to the analog amplifier 161. In this case, the audio data processor 160 converts digital audio data into an analog audio signal based on the volume signal supplied from the CPU 151. The audio data processor 160 also supplies, for example, PCM-encoded digital audio data, to the digital amplifier 191 (FIG. 4) of the sound output unit 122 of the APR 112.

The analog amplifier 161 amplifies the analog audio signal supplied from the audio data processor 160, and then supplies the amplified analog audio signal to the built-in loudspeaker 162 or the analog sound output unit 163. The analog amplifier 161 detects the connecting state of an external audio unit, for example, a headphone, connected to the analog sound output unit 163. If an external audio unit is connected to the analog sound output unit 163, the analog amplifier 161 stops supplying the audio signal to the built-in loudspeaker 162 and supplies an audio-unit connecting signal to the embedded controller 155. When a mute signal is supplied from the embedded controller 155, the analog amplifier 161 stops supplying the audio signal to the built-in loudspeaker 162 and the analog sound output unit 163.

The built-in loudspeaker 162 outputs sound based on the analog audio signal supplied from the analog amplifier 161.

The analog sound output unit 163 is, for example, an earphone jack, and outputs an analog audio signal supplied from the analog amplifier 161 to an external audio unit, such as a headphone, connected to the analog sound output unit 163.

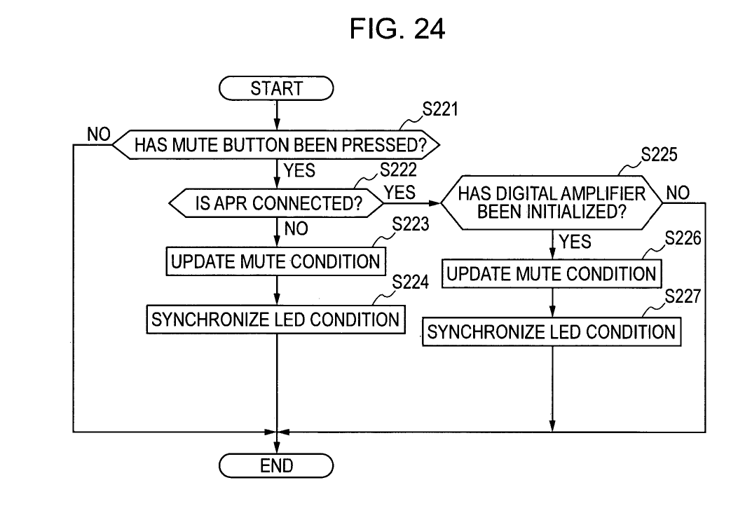

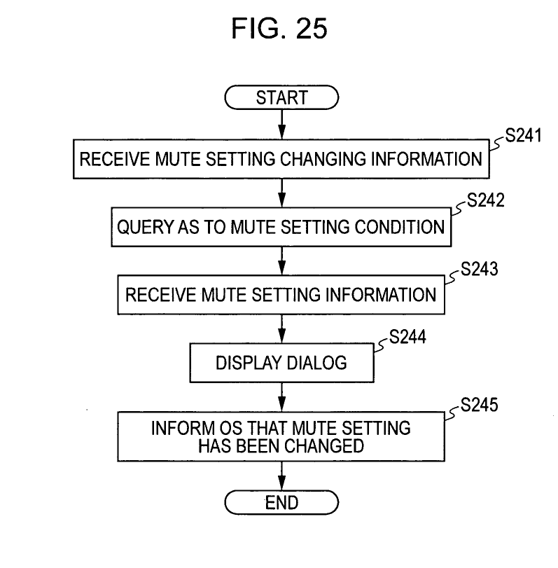

The display unit 164 is connected to the CPU 151 via a bus or a hub (not shown). The display unit 164 is formed of a display, such as a cathode ray tube (CRT) or a liquid crystal display (LCD), and displays various types of information and statuses of the personal computer 111. The display unit 164 displays a dialog indicating the mute setting status of the information processing system 101, which is discussed in detail below with reference to FIGS. 26 and 27.

The drive 165 is connected to the CPU 151 via a bus or a hub (not shown). The removable medium 181, such as a magnetic disk, an optical disc, a magneto-optical disk, or a semiconductor memory, is installed in the drive 165. The drive 165 then reads or writes data from or into the removable medium 181. The drive 165 may be provided for the APR 112 or the BPR 113.

FIG. 4 illustrates an example of the functional configuration of the sound output unit 122 of the APR 112. The sound output unit 122 includes the digital amplifier 191, a loudspeaker 192, a volume switch 193, and a digital sound output unit 194.

The digital amplifier 191 receives, for example, PCM audio data, from the audio data processor 160. The digital amplifier 191 also receives volume gain data from the embedded controller 155. The digital amplifier 191 drives the loudspeaker 192 with the volume gain indicated in the volume gain data based on the received audio data. For example, the digital amplifier 191 supplies to the loudspeaker 192 an analog audio signal generated by allowing a pulse width modulation (PWM) signal corresponding to the PCM audio data based on the volume gain indicated in the volume gain data to pass through a low-pass filter (not shown). The digital amplifier 191 stops driving the loudspeaker 192 when a mute signal is supplied from the embedded controller 155.

The loudspeaker 192 outputs sound when being driven by the digital amplifier 191.

The volume switch 193 is provided with, for example, a volume knob. When a user operates the volume knob of the volume switch 193, the volume switch 193 supplies a switch volume signal in accordance with the position of the volume knob to the embedded controller 155.

The digital sound output unit 194 receives, for example, PCM audio data, from the audio data processor 160. The digital sound output unit 194 outputs the received digital audio data to an external audio unit connected to the digital sound output unit 194.

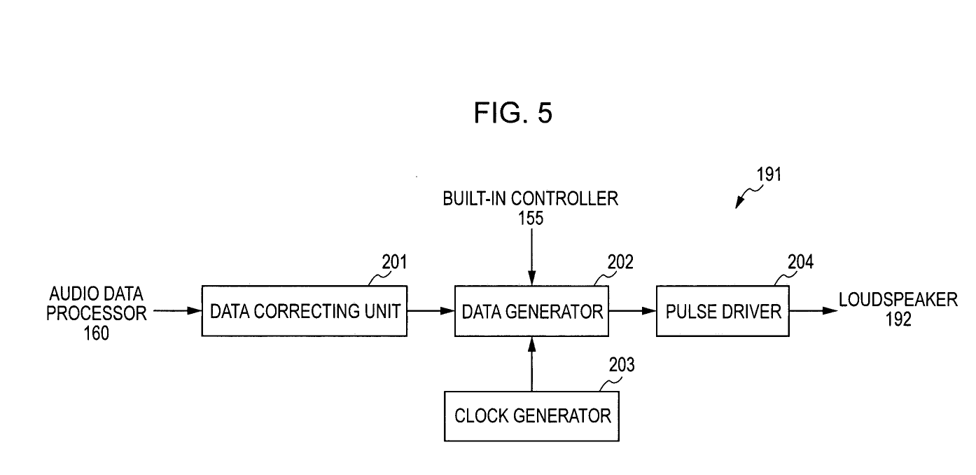

FIG. 5 illustrates an example of the configuration of the digital amplifier 191 shown in FIG. 4. The digital amplifier 191 includes a data correcting unit 201, a data generator 202, a clock generator 203, and a pulse driver 204.

The data correcting unit 201 receives, for example, PCM audio data, from the audio data processor 160, and corrects the audio data by, for example, removing jitter. The data correcting unit 201 supplies the corrected audio data to the data generator 202.

The data generator 202 receives the volume gain data from the embedded controller 155. The data generator 202 operates in synchronization with a clock signal supplied from the clock generator 203, and generates audio data suitable for driving the loudspeaker 192 from the audio data supplied from the data correcting unit 201 based on the volume gain indicated in the volume gain data, and supplies the generated audio data to the pulse driver 204. For example, the data generator 202 generates PWM audio data from PCM audio data supplied from the data correcting unit 201.

The pulse driver 204 generates an audio signal by switching ON the power source (voltage) based on the audio data (pulse signal) supplied from the data generator 202, and allows the generated audio signal to pass through a low-pass filter (not shown) and supplies the resulting audio signal to the loudspeaker 192.

When receiving a mute signal from the embedded controller 155, the data generator 202 stops supplying the audio data to the pulse driver 204.

The volume set by the volume button 157 or by the function of the OS or an application program executed by the CPU 151, i.e., the volume set by the personal computer 111, is referred to as the “system volume”, and the volume set by the volume switch 193, i.e., the volume set by the APR 112, is referred to as the “switch volume”. The sound volume output from the built-in loudspeaker 162 of the personal computer 111 is set by the system volume, while the sound volume output from the loudspeaker 192 of the APR 112 is set by the system volume and the switch volume, which is discussed below with reference to FIGS. 13 through 15. The system volume may be set by the user such that the right-side system volume and the left-side system volume are independently set or that the same system volume is set for the left and right sides.

The programs executed by the personal computer 111 include, as shown in FIG. 6, embedded control firmware (hereinafter simply referred to as the “EC firmware”) 221, a basic input output system (BIOS) 222, a driver 223, an OS 224, an application program 225, and a utility program 226. The EC firmware 221 is executed by the embedded controller 155, while the BIOS 222, the driver 223, the OS 224, the application program 225, and the utility program 226 are executed by the CPU 151.

Details of the EC firmware 221 are given below with reference to FIG. 7. The EC firmware 221 performs the following processing without using other programs, such as the OS 224: controlling the keyboard 156, the volume button 157, the mute button 158, and the LED 159, controlling the power of the personal computer 111, detecting the connecting state of the APR 112 or the BPR 113, controls the volume of the information processing system 101, and controlling the mute setting of the information processing system 101.

The EC firmware 221 (embedded controller 155) directly sends and receives data or information to and from the utility program 226 (CPU 151) without using another software, such as the OS 224. The EC firmware 221 supplies to the utility program 226 port replicator connecting-state changing information indicating that a port replicator is installed or removed into or from the personal computer 111 or port replicator connecting information indicating whether a port replicator is installed or whether the installed port replicator is the APR 112 or the BPR 113. The EC firmware 221 also supplies to the utility program 226 mute setting changing information indicating that the mute button 158 has been pressed so that the mute setting of the information processing system 101 has been changed or mute setting information indicating whether the mute setting is ON or OFF.

The EC firmware 221 supplies a volume-increasing signal or a volume-decreasing signal from the volume button 157 to the OS 224 via the utility program 226.

The BIOS 222 is a program for providing basic input/output control functions dependent on hardware of the personal computer 111. The operation of the personal computer 111 from when the personal computer 111 is powered ON to when the OS 224 is started is controlled by the BIOS 222.

The driver 223 is a program for controlling various units of hardware of the personal computer 111 by using the functions of the BIOS 222.

The OS 224 is a basic program, e.g., Windows®XP by Microsoft Corporation or Mac OS by Apple® Computer, Inc. for controlling the basic operations of a computer. The functions provided by the OS 224 include a system volume setting function for setting the system volume of the information processing system 101 and a mute setting function for performing the mute setting of the information processing system 101.

When the user sets the system volume by operating the system volume setting function or the volume button 157, the OS 224 supplies OS system volume data indicating the system volume set by the user to the utility program 226. For example, when the right system volume and the left system volume are independently set, the OS system volume data indicates that the right system volume and left system volume are independently set and also indicates right and left system volumes, for example, 16-bit data each. When the same system volume is set for the right side and the left side, the OS system volume data indicates that the same system volume is set for the right side and the left side and also indicates the right-and-left common system volume, for example, 16-bit data.

When the user sets the mute setting function so that the mute setting of the information processing system 101 is turned ON or OFF, the OS 224 supplies mute setting changing information to the utility program 226.

The application program 225 is software that provides specific functions, such as word-processing, spreadsheets, and databases, by using the functions of the OS 224.

The utility program 226 complements the functions of the OS 224 and the application program 225. When receiving the OS system volume data indicating that the right-side system volume and the left-side system volume are independently set from the OS 224, the utility program 226 converts, for example, each of the 16-bit right OS system volume data and the 16-bit left OS system volume data, into 20-level right system volume data and 20-level left system volume data, respectively, and supplies the right and left system volume data to the EC firmware 221. If the OS system volume data indicating that the same system volume is set for the right and left sides is received, the utility program 226 converts, for example, 16-bit right-and-left common OS system volume data into 20-level right-and-left common system volume data, and supplies it to the EC firmware 221.

When receiving the mute setting changing information from the EC firmware 221, the utility program 226 supplies mute setting query information indicating an instruction to query as to the mute setting state of the information processing system 101 to the EC firmware 221. When receiving the port replicator connecting-state changing information from the EC firmware 221, the utility program 226 supplies to the EC firmware 221 port replicator connecting-state query information indicating an instruction to query as to details of the connecting state of the port replicator connected to the personal computer 111.

When receiving from the OS 224 mute setting changing information indicating that the mute setting is turned ON, the utility program 226 supplies mute setting ON instruction information to the EC firmware 221. When receiving mute setting changing information indicating that the mute setting is turned OFF, the utility program 226 supplies mute setting OFF instruction information to the EC firmware 221.

FIG. 7 is a block diagram illustrating an example of the functional configuration implemented by the embedded controller 155 executing the EC firmware 221. When the embedded controller 155 executes the EC firmware 221, a hardware signal input unit 241, a port replicator connection detector 242, a volume switch detector 243, a volume controller 244, a mute controller 245, a utility communication unit 246, a digital amplifier controller 247, a display controller 248, a keyboard controller 249, and a power controller 250 are implemented.

The hardware signal input unit 241 receives the APR connecting signal from the connecting signal output unit 121 of the APR 112 when the APR 112 is connected to the personal computer 111, and receives the BPR connecting signal from the connecting signal output unit 131 of the BPR 113 when the BPR 113 is connected to the personal computer 111. The hardware signal input unit 241 supplies the received APR connecting signal or the BPR connecting signal to the port replicator connection detector 242.

The hardware signal input unit 241 receives a volume-increasing signal or a volume-decreasing signal from the volume button 157, and supplies the volume-increasing signal or the volume-decreasing signal to the CPU 151 (utility program 226) via the utility communication unit 246. The hardware signal input unit 241 also receives a mute button signal from the mute button 158, and supplies the mute button signal to the mute controller 245. The hardware signal input unit 241 also receives a switch volume signal from the volume switch 193 and supplies the switch volume signal to the volume switch detector 243.

When the APR 112 or the BPR 113 is installed or removed into or from the personal computer 111, the port replicator connection detector 242 supplies port replicator connecting-state changing information to the CPU 151 (utility program 226) via the utility communication unit 246 based on the APR connecting signal or the BPR connecting signal.

The port replicator connection detector 242 also receives port replicator connecting-state query information from the CPU 151 (utility program 226) via the utility communication unit 246. In response to the port replicator connecting-state query information, the port replicator connection detector 242 supplies the port replicator connecting information to the CPU 151 via the utility communication unit 246. The port replicator connection detector 242 also supplies the port replicator connecting information to the volume controller 244 and the mute controller 245.

The volume switch detector 243 converts a switch volume signal into digital switch volume data and supplies the converted switch volume data to the volume controller 244. In this case, the volume switch detector 243 first converts the switch volume signal into, for example, 10-bit (1024 levels) digital data, and then performs predetermined conversion on the digital data by, for example, adding an offset value to the digital data. Then, the volume switch detector 243 truncates the lower 4 bits of the converted data, and sets the resulting 6-bit (64 levels) data ranging from 00000 to 11111 in binary format to be the switch volume data.

The volume controller 244 controls a flag indicating whether the right system volume and the left system volume are independently set (hereinafter referred to as the “right-and-left independent volume setting flag”). When the user determines that the right system volume and the left system volume are independently set, the volume controller 244 turns ON the right-and-left independent volume setting flag. When the user determines that the same system volume is set for the right side and the left side, the volume controller 244 turns OFF the right-and-left independent volume setting flag.

The volume controller 244 receives the right-and-left common system volume data, the right system volume data, and the left system volume data from the CPU 151 (utility program 226) via the utility communication unit 246.

The volume controller 244 calculates the volume gain based on the switch volume data, the right-and-left common system volume data, the right system volume data, and the left system volume data, which is described below with reference to FIGS. 13 through 15, and supplies the volume gain data to the digital amplifier 191 via the digital amplifier controller 247.

The volume controller 244 manages volume change flags indicating the occurrence of an event that changes the volume by, for example, the user operating the volume button 157 or the volume switch 193 or using the system volume setting function of the OS 224. The volume change flags include three flags, i.e., a right-and-left common volume change flag, a right volume change flag, and a left volume change flag. The volume controller 244 manages the right volume change flag and the left volume change flag when the right system volume and the left system volume are independently set, and manages the right-and-left common volume change flag when the same system volume is set for the right side and the left side.

The volume controller 244 manages volume-calculated flags indicating whether the volume gain has been calculated. The volume-calculated flags include three flags, i.e., a right-and-left common volume calculated flag, a right volume calculated flag, and a left volume calculated flag. The volume controller 244 manages the right volume calculated flag and the left volume calculated flag when the right system volume and the left system volume are independently set, and manages the right-and-left common volume calculated flag when the same system volume is set for the right side and the left side.

The mute controller 245 receives mute setting ON instruction information or mute setting OFF instruction information from the CPU 151 (utility program 226) via the utility communication unit 246. The mute controller 245 turns ON or OFF the mute setting of the information processing system 101 based on the mute button signal and the mute setting ON instruction information or the mute setting OFF instruction information. The mute controller 245 manages the mute setting flag, and turns ON the mute setting flag when the mute setting is ON and turns OFF the mute setting flag when the mute setting is OFF.

The mute controller 245 receives an audio-unit connecting signal from the analog amplifier 161. The mute controller 245 supplies a mute signal to the analog amplifier 161 and the digital amplifier 191 based on the mute setting, port replicator connecting information, and audio-unit connecting signal.

The mute controller 245 receives the mute setting query information from the CPU 151 (utility program 226) via the utility communication unit 246. In response to the mute setting query information, the mute controller 245 supplies the mute setting information to the CPU 151 via the utility communication unit 246.

The utility communication unit 246 communicates with the utility program 226 executed by the CPU 151, and supplies and receives data or information to and from the utility program 226.

The digital amplifier controller 247 initializes the digital amplifier 191 and supplies the volume gain data to the digital amplifier 191. The digital amplifier controller 247 also manages a flag indicating whether the digital amplifier 191 has been initialized (hereinafter referred to as the “digital amplifier initializing flag”).

The display controller 248 turns ON the LED 159 when the mute setting of the information processing system 101 is. ON, and turns OFF the LED 159 when the mute setting is OFF.

The keyboard controller 249 controls the operation input from the keyboard 156, and supplies information indicating the key status of the keyboard 156 to the CPU 151, the mute controller 245, and the utility communication unit 246 if necessary.

The power controller 250 monitors the remaining amount of batteries (not shown) or the temperature of the personal computer 111, and controls the power consumption of the individual elements of the personal computer 111.

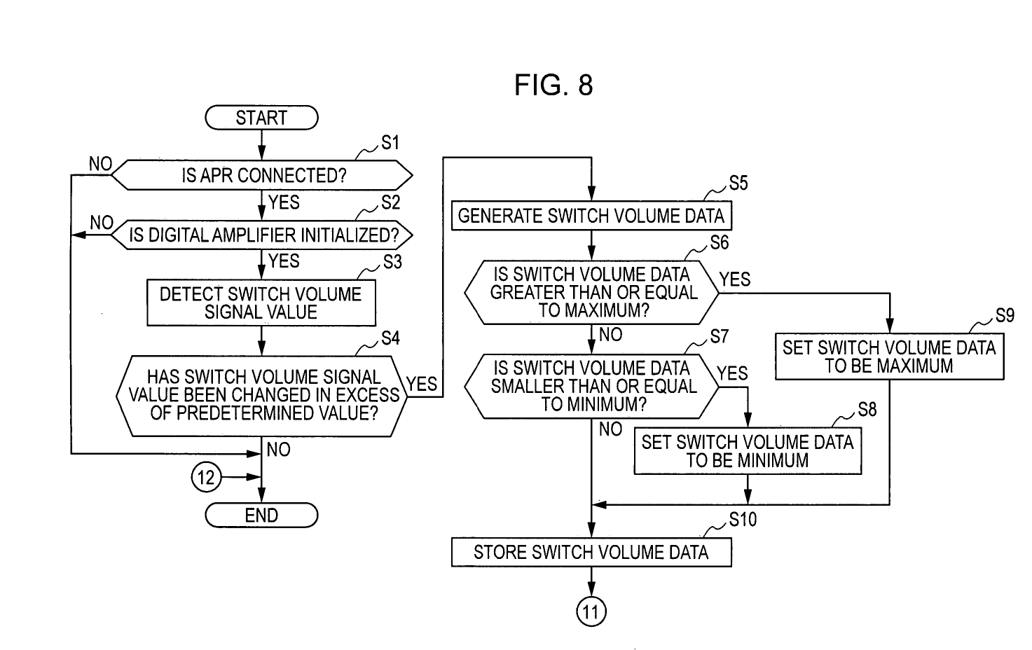

The operation of the information processing system 101 is described below with reference to FIGS. 8 through 27.

A description is first given, with reference to FIGS. 8 through 18, of volume setting processing for the APR 112 by the information processing system 101.

Switch volume polling processing performed by the embedded controller 155 executing the EC firmware 221 is discussed below. This processing is executed at regular intervals (for example, every 15 ms) when the personal computer 111 is powered ON.

In step S1, the port replicator connection detector 242 determines whether the APR 112 is connected. If it is determined in step S1 that the APR 112 is connected, i.e., the APR connecting signal is supplied from the connecting signal output unit 121 of the APR 112 via the hardware signal input unit 241, the process proceeds to step S2.

In step S2, the digital amplifier controller 247 determines whether the digital amplifier 191 has been initialized. If the digital amplifier 191 has been initialized, i.e., if the digital amplifier initializing flag is ON, the process proceeds to step S3.

In step S3, the volume switch detector 243 detects the value of a switch volume signal. More specifically, the volume switch detector 243 receives a switch volume signal from the volume switch 193 via the hardware signal input unit 241, and converts the switch volume signal into, for example, 10-bit digital data, and stores it.

Then, in step S4, the volume switch detector 243 compares the switch volume signal value stored in step S3 with the switch volume signal value stored in the previous switch volume polling processing, and determines whether the difference between the two signal values exceeds a predetermined value, i.e., whether the switch volume signal value has been changed in excess of the predetermined value. If the difference does not exceed the predetermined value, the switch volume polling processing is completed.

If it is determined in step S4 that the switch volume signal value has been changed in excess of the predetermined value, i.e., that the switch volume signal value supplied from the volume switch 193 has been changed in excess of the predetermined value by the user operating the volume switch 193 or by the APR 112 connected to the personal computer 111, the process proceeds to step S5.

In step S5, the volume switch detector 243 generates switch volume data. More specifically, the volume switch detector 243 performs predetermined conversion by, for example, adding an offset value to the 10-bit (1024 levels) digital data stored in step S3, and then truncates the lower 4-bit data to generate 6-bit (64 levels) switch volume data.

Then, in step S6, the volume switch detector 243 determines whether the switch volume data is greater than or equal to a predetermined maximum value. If the switch volume data is found to be smaller than the predetermined maximum value, the process proceeds to step S7.

In step S7, the volume switch detector 243 determines whether the switch volume data is smaller than or equal to a predetermined minimum value. If the switch volume data is found to be greater than the minimum value, the process proceeds to step S10.

If it is determined in step S7 that the switch volume data is smaller than or equal to the minimum value, the process proceeds to step S8. In step S8, the volume switch detector 243 sets the switch volume data value to be the predetermined minimum value. Then, the process proceeds to step S10.

If it is determined in step S6 that the switch volume data is greater than or equal to the maximum value, the process proceeds to step S9. In step S9, the volume switch detector 243 sets the switch volume data value to be the predetermined maximum value. Then, the process proceeds to step S10.

In step S10, the volume switch detector 243 stores the switch volume data.

In step S11, the volume switch detector 243 calculates the average of the switch volume data. More specifically, the volume switch detector 243 averages the switch volume data stored in step S10 and a predetermined number of switch volume data stored in the past switch volume polling processing, and stores the calculated average of the switch volume data.

In step S12, the volume switch detector 243 compares the average of the current switch volume data calculated in step S11 with the average of the switch volume data calculated in the previous switch volume polling processing, and determines whether the difference between the two averages is greater than or equal to a predetermined value. If the difference between the average of the current switch volume data and the average of the previous switch volume data is greater than or equal to the predetermined value, i.e., if the average of the switch volume data has been changed by the predetermined value by the user operating the volume switch 193, the process proceeds to step S13.

In step S13, the volume controller 244 updates the switch volume. More specifically, the volume switch detector 243 supplies the switch volume data stored in step S10 to the volume controller 244. The volume controller 244 overwrites the switch volume by the supplied new switch volume data. The stored switch volume is used for volume gain calculating processing, which is discussed below with reference to FIG. 13, until a new switch volume is stored in step S13 in the subsequent switch volume polling processing.

In step S14, the volume controller 244 determines based on the right-and-left independent volume setting flag whether the right system volume and the left system volume are independently set. If it is determined in step S14 that the right and left system volumes are not independently set, i.e., the right-and-left independent volume setting flag is OFF, the process proceeds to step S15.

In step S15, the volume controller 244 turns ON the right-and-left common volume change flag, and the switch volume polling processing is completed.

If it is determined in step S14 that the right and left system volumes are set independently, the process proceeds to step S16. In step S16, the volume controller 244 turns ON the right volume change flag and the left volume change flag, and then, the switch volume polling processing is completed.

If it is determined in step S12 that the difference between the average of the current switch volume data and the average of the previous switch volume data is smaller than the predetermined value, the switch volume is not updated, and the switch volume polling processing is completed.

If it is determined in step S1 that the APR 112 is not connected or if it is determined in step S2 that the digital amplifier 191 has not been initialized, the switch volume polling processing is terminated.

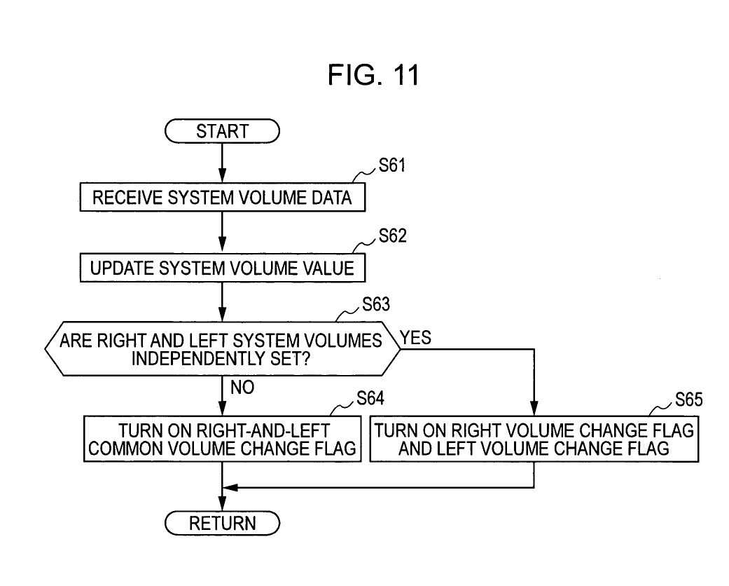

In the above-described switch volume polling processing, the right-and-left common volume change flag is turned ON or the right volume change flag and the left volume change flag are turned ON. Accordingly, the volume gain of the digital amplifier 191 of the APR 112 is calculated in the APR volume calculating processing, which is discussed below with reference to FIG. 12. The switch volume polling processing can be performed merely by using the embedded controller 155 without using the CPU 151 (OS 224). Thus, the switch volume can be changed by operating the volume switch 193 even if the OS 224 is not operated.

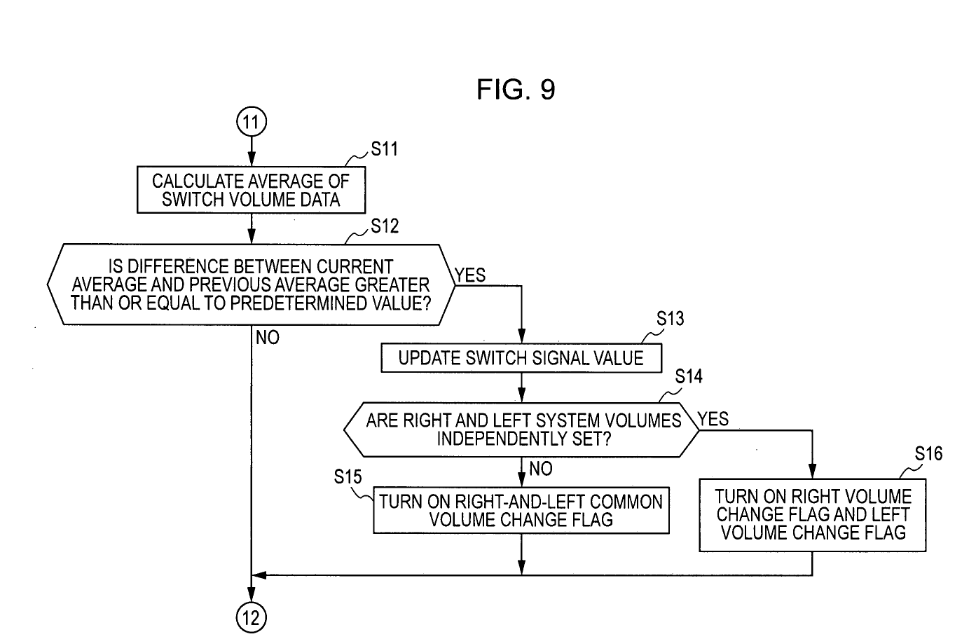

A description is now given, with reference to FIG. 10, of system volume informing processing performed by the CPU 151 executing the utility program 226.

When the user uses the system volume setting function of the OS 224 or operates the volume button 157, or when the personal computer 111 is powered ON to start the OS 224 by the CPU 151, the OS 224 supplies OS system volume data indicating the system volume to the utility program 226.

In step S41, the utility program 226 receives the OS system volume data from the OS 224.

In step S42, the utility program 226 determines based on the OS system volume data whether the right system volume and the left system volume are independently set. If it is determined in step S42 that the right system volume and the left system volume are not independently set, the process proceeds to step S43.

In step S43, the utility program 226 generates right-and-left common system volume data. More specifically, the utility program 226 converts 16-bit OS system volume data into 20-level right-and-left common system volume data.

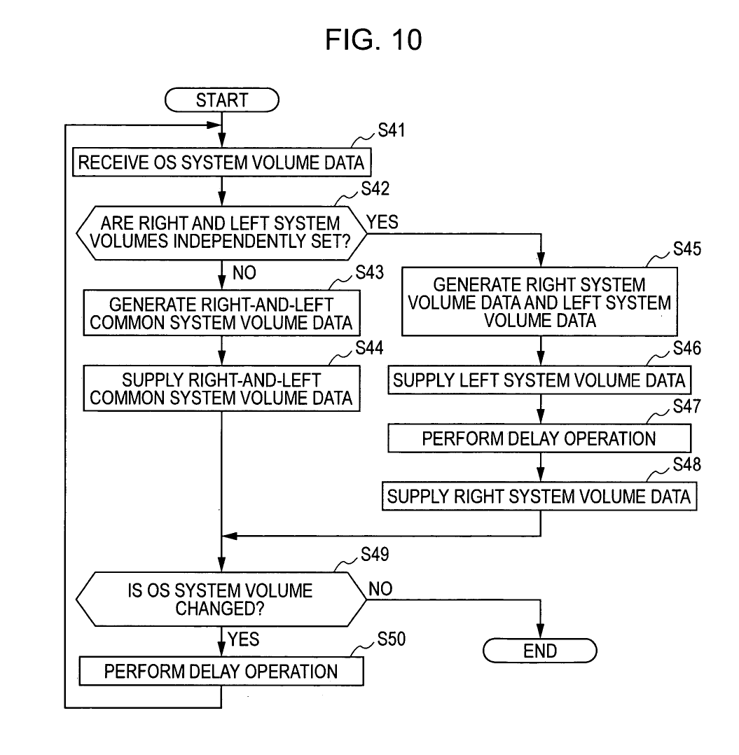

In step S44, the utility program 226 supplies the right-and-left common system volume data to the volume controller 44 via the utility communication unit 246. The volume controller 44 receives the right-and-left common system volume data in step S61 of FIG. 11, which is discussed later. The process then proceeds to step S49.

If it is determined in step S42 that the right system volume and the left system volume are independently set, the process proceeds to step S45. In step S45, the utility program 226 generates right system volume data and left system volume data. More specifically, the utility program 226 converts, for example, each of 16-bit right and left system volume data, into 20-level right system volume data and 20-level left system volume data.

In step S46, the utility program 226 supplies the left system volume data to the volume controller 244 via the utility communication unit 246. The volume controller 244 receives the left system volume data in step S61 of FIG. 11, which is discussed later.

In step S47, the utility program 226 performs a delay operation. More specifically, the utility program 226 delays the execution of the subsequent step by a predetermined time (for example, several milliseconds). This delay operation is performed so that a heavy load is not imposed on the CPU 151 and the embedded controller 155 that receives the system volume.

In step S48, the utility program 226 supplies the right system volume data to the volume controller 244 via the utility communication unit 246. The volume controller 244 receives the right system volume data in step S61 of FIG. 11, which is discussed later. The process then proceeds to step S49.

In step S49, the utility program 226 determines whether the OS system volume is changed. If it is determined that the OS system volume is changed, i.e., if the OS system volume data is still being supplied from the OS 224 because the user continues to use the system volume setting function of the OS 224 or to operate the volume button 157, the process proceeds to step S50.

As in step S47, in step S50, the utility program 226 performs a delay operation.

The process then returns to step S41, and steps S41 through S50 are repeated, i.e., the system volume data is supplied to the embedded controller 155, until it is determined in step S49 that the OS system volume is no longer changed.

If it is determined in step S49 that the OS system volume is no longer changed, the system volume informing processing is completed.

A description is now given, with reference to the flowchart of FIG. 11, of system volume receiving processing performed by the embedded controller 155 executing the EC firmware 221 in association with the system volume informing processing shown in FIG. 10 performed by the utility program 226.

In step S61, the volume controller 244 receives the system volume data. More specifically, the volume controller 244 receives via the utility communication unit 246 the right-and-left common system volume data supplied from the utility program 226 in step S44 of FIG. 10 or the left system volume data supplied from the utility program 226 in step S46 of FIG. 10 and the right system volume data supplied from the utility program 226 in step S48 of FIG. 10.

In step S62, the volume controller 244 updates the system volume value. More specifically, the volume controller 244 stores the right-and-left common system volume data or the right system volume data and the left system volume data received in step S61 as a new right-and-left common system volume or new right and left system volumes, respectively. The stored system volumes are used for the volume gain calculating processing, which is discussed later with reference to FIG. 13, until a new system volume is stored in step S62.

In step S63, the volume controller 244 determines whether the right system volume and the left system volume are independently set, as in step S14 of FIG. 9. If it is determined in step S63 that the right and left system volumes are not independently set, the process proceeds to step S64.

In step S64, the volume controller 244 turns ON the right-and-left common volume change flag, and the system volume receiving processing is then completed.

If it is determined in step S63 that the right and left system volumes are independently set, the process proceeds to step S65. In step S65, the volume controller 244 turns ON the right volume change flag and the left volume change flag, and the system volume receiving processing is completed.

In this system volume receiving processing, the right-and-left common volume change flag is turned ON or the right volume change flag and the left volume change flag are turned ON. Accordingly, the volume gain of the digital amplifier 191 of the APR 112 is calculated in the APR volume calculating processing, which is discussed later with reference to FIG. 12.

The APR volume calculating processing performed by the embedded controller 155 executing the EC firmware 221 is described below with reference to FIG. 12. This processing is performed at regular intervals, for example, 15 ms, when the personal computer 111 is powered ON.

In step S81, the port replicator connection detector 242 determines whether the APR 112 is connected to the personal computer 111, as in step S1 of FIG. 8. If it is determined that the APR 112 is connected, the process proceeds to step S82.

In step S82, the digital amplifier controller 247 determines whether the digital amplifier 191 of the APR 112 has been initialized, as in step S2 of FIG. 8. If it is determined that the digital amplifier 191 has been initialized, the process proceeds to step S83.

In step S83, the volume controller 244 determines whether the right-and-left common volume change flag is ON. If the right-and-left common volume change flag is found to be ON, i.e., if the right-and-left common volume change flag is ON in step S15 of FIG. 9 or step S64 of FIG. 11, the process proceeds to step S84.

In step S84, the volume controller 244 turns OFF the right-and-left common volume change flag.

In step S85, the volume controller 244 turns ON the right-and-left common volume calculated flag.

In step S86, the volume controller 244 sets the right-and-left common system volume stored in step S62 of FIG. 11 as the system volume used for the volume gain calculating processing in step S95. The process then proceeds to step S95.

If it is determined in step S83 that the right-and-left common volume change flag is OFF, the process proceeds to step S87.

In step S87, the volume controller 244 determines whether the left volume change flag is ON. If the left volume change flag is found to be ON, i.e., if the left volume change flag in step S16 of FIG. 9 or in step S65 of FIG. 11 is ON, the process proceeds to step S88.

In step S88, the volume controller 244 turns OFF the left volume change flag.

In step S89, the volume controller 244 turns ON the left volume calculated flag.

In step S90, the volume controller 244 sets the left system volume stored in step S62 of FIG. 11 as the system volume used for the volume gain calculating processing in step S95. The process then proceeds to step S95.

If it is determined in step S87 that the left volume change flag is OFF, the process proceeds to step S91 to determine whether the right volume change flag is ON. If the right volume change flag is found to be ON, i.e., if the right volume change flag is ON in step S16 of FIG. 9 or step S65 of FIG. 11 and if the left volume change flag is OFF in step S88, the process proceeds to step S92.

In step S92, the volume controller 244 turns OFF the right volume change flag.

In step S93, the volume controller 244 turns ON the right volume calculated flag.

In step S94, the volume controller 244 sets the right system volume stored in step S62 of FIG. 11 as the system volume used for the volume gain calculating processing in step S95. The process then proceeds to step S95.

In step S95, the volume controller 244 performs the volume gain calculating processing, and then, the APR volume calculating processing is completed. In the volume gain calculating processing, the volume gain of the digital amplifier 191 is calculated. Details of the volume gain calculating processing are given below with reference to FIG. 13.

If it is determined in step S91 that the right volume change flag is OFF, i.e., that neither of the system volume nor the switch volume has been changed by a predetermined value and that the right-and-left common volume change flag and the right and left volume change flags are OFF, the APR volume calculating processing is terminated.

If it is determined in step S81 that the APR 112 is not connected or if it is determined in step S82 that the digital amplifier 191 has not been initialized, the APR volume calculating processing is terminated.

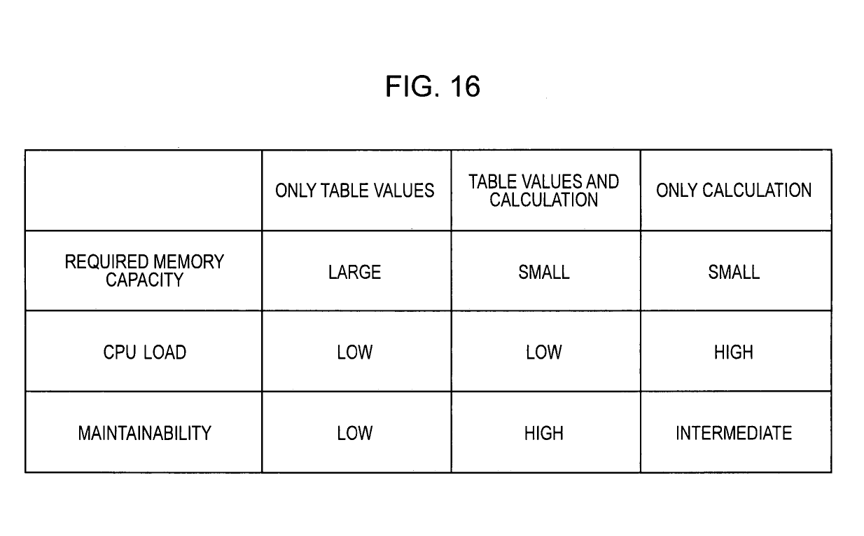

In the APR volume calculating processing, the right-and-left common volume calculated flag, the right volume calculated flag, or the left volume calculated flag is turned ON. Accordingly, in the APR volume setting processing, which is discussed below with reference to FIG. 17, the volume gain data is supplied to the digital amplifier 191 of the APR 112 so that the sound volume output from the loudspeaker 192 of the APR 112 can be set.

Details of the volume gain calculating processing in step S95 of FIG. 12 are described below with reference to the flowchart of FIG. 13.

In step S111, the volume controller 244 determines whether the system volume is set to be 0. If it is determined that the system volume is not set to be 0, the process proceeds to step S112 to determine whether the switch volume is set to be 0. If it is determined that the switch volume is set to be 0, the process proceeds to step S113.

If it is determined in step S111 that the system volume is set to be 0, the process proceeds to step S113 by skipping step S112.

In step S113, the volume controller 244 obtains the prestored volume gain of the mute level (which is almost equivalent to the mute state). The process then proceeds to step S117.

If it is determined in step S112 that the switch volume is not set to be 0, i.e., that neither of the system volume nor the switch volume is set to be 0, the process proceeds to step S114.

Steps S114 through S116 are described below while discussing the volume gain calculation method performed by the volume controller 244.

The volume gain of the digital amplifier 191 is 13-bit data containing 8-bit mantissa data and 5-bit exponent data. In the information processing system 101, among 256 (8-bit) mantissa data, 8 mantissa data are predetermined, and mantissa pointers ranging from 000 to 111 in binary format are assigned to the 8 mantissa data.

The volume controller 244 uses the 8-bit gain calculated value represented by exponent data+mantissa pointer. That is, the first 5 bits of the gain calculated value are exponent data, and the remaining 3 bits are the mantissa pointer. For example, if the gain calculated value is 01101010 in binary format, the first 5 bits 01101 are exponent data and the remaining 3 bits 010 are the mantissa pointer.

In the information processing system 101, among the 8-bit gain calculated values, 19 different gain calculated values (hereinafter referred to as the “reference gain calculated values”) are predetermined, and the reference gain calculated values are assigned to the corresponding 19-level system volumes other than the level system volume 0 among the 20-level system volumes.

In step S114, the volume controller 244 sets the reference gain calculated value based on the system volume. That is, the volume controller 244 sets the reference gain calculated value corresponding to the system volume.

In step S115, the volume controller 244 adds the switch volume to the reference gain calculated value, and sets the resulting value as the gain calculated value.

For example, the volume controller 244 adds the value obtained by subtracting one from the switch volume to the reference gain calculated value. As stated above, when the switch volume is 0, the volume gain is not calculated, and the switch volume is 6-bit data ranging from 000000 to 111111. Accordingly, when the switch volume is 000001 to 111111 in binary format, the volume controller 244 adds 000000 to 111110 to the reference gain calculated value. Thus, when the switch volume is 1, the reference gain value and the gain calculated value are the same.

For example, when the minimum value (when the system volume is 1) of the reference gain calculated value is 00000110 and when the maximum value (when the system volume is 19) of the reference gain calculated value is 01001100, the gain calculated value ranges from 00000110 (=00000110+(000001-000001)) to 10001010 (=01001100+(111111-000001)).

If the reference gain calculated value is 00001101 and if the switch volume is 000010, the gain calculated value results in 00001110 (=00001101+(000010-000001)), and the exponent data is 00001 and the mantissa pointer is 110. If the switch volume is 000011, the gain calculated value is 00001111 (=00001101+(000011-000001)), and the exponent data is 00001 and the mantissa pointer is 111. That is, as the switch volume increases by one, the mantissa pointer also increases by one. If the switch volume is 000100, the gain calculated value results in 00010000 (=00001101+(000100-000001)), and the exponent data is 00010 and the mantissa pointer is 000. That is, the mantissa pointer returns from 111 to 000, and the exponent data increases by one. That is, the mantissa pointer loops from 000 to 111, and when the mantissa pointer returns from 111 to 000, the exponent data is increased by one.

It is now assumed that the reference gain calculated value is B, the two switch volume values are S1 and S2, the gain calculated value corresponding to the switch volume value S1 is C1, the exponent data and the mantissa pointer of the gain calculated value C1 are E1 and P1, respectively, the gain calculated value corresponding to the switch volume value S2 is C2, the exponent data and the mantissa pointer of the gain calculated value C2 are E2 and P2, respectively, and the mantissa data to which the mantissa pointer P1 is assigned and the mantissa data to which the mantissa pointer P2 is assigned are M1 and M2, respectively. In this case, the following equations (1) and (2) hold true.
C1=B+S1−1 (1)
C2=B+S2−1 (2)

When the switch volume S2 is greater than the switch volume S1 by one and when the mantissa pointer P1 is other than 111 in binary format, the mantissa pointer P2 is greater than the mantissa pointer P1 by one, and the exponent data E1 and the exponent data E2 are equal to each other. When the switch volume S2 is greater than the switch volume S1 by one and when the mantissa pointer P1 is 111 in binary format, the mantissa pointer P2 becomes 000 in binary format, and the exponent data E2 is greater than the exponent data E1.

That is, when the switch volume is increased by one, the mantissa pointer is increased by one, and when the mantissa pointer reaches 111, it is returned to 000, and the exponent data is increased by one. Accordingly, the gain calculated value C1 and the gain calculated value C2 satisfying the conditions that E1=E2 and P1+1=P2 are adjacent to each other. Also, the gain calculated value C1 and the gain calculated value C2 satisfying the conditions that E1+1=E2 and P1=111 (binary) and P2=000 are adjacent to each other.

Accordingly, when C1+1=C2, i.e., when the gain calculated value C1 and the gain calculated value C2 are adjacent to each other, it is now assumed that the volume gain (exponent data E1 and mantissa data M1) corresponding to the gain calculated value C1 and the volume gain (exponent data E2 and mantissa data M2) corresponding to the gain calculated value C2 are set. Then, the 8 mantissa data are selected so that the difference of the sound pressure level (decibel) of audio data output from the digital amplifier 191 can be almost uniform, i.e., so that the sound pressure levels of the audio data output from the digital amplifier 191 are proportional to the gain calculated values. As a result, the sound pressure level of sound output from the loudspeaker 192 can be almost linearly changed based on the system volume and the switch volume.

As described above, the volume gain is calculated by assigning one of the reference gain calculated values to the corresponding system volume and by adding the switch volume to the reference gain calculated value. Alternatively, however, the reference gain calculated value may be assigned to the switch volume, and the system volume may be added to the reference gain calculated value.

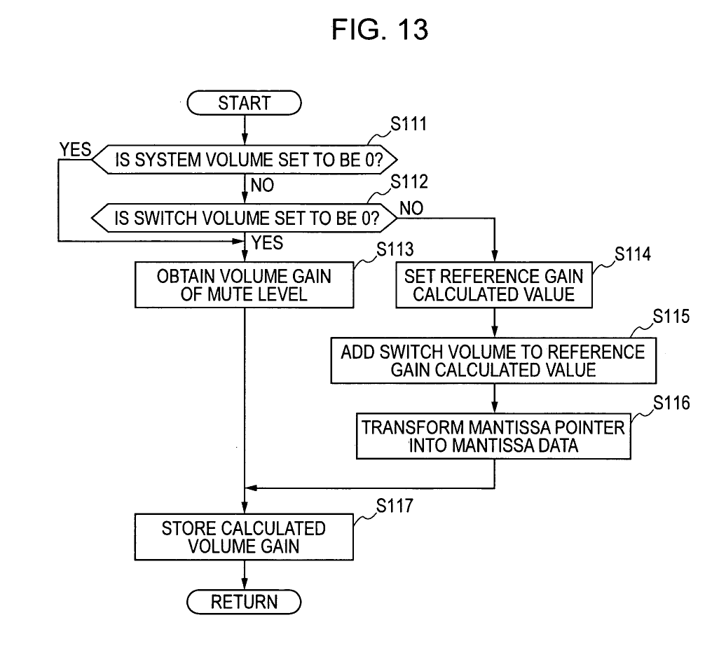

FIG. 14 illustrates a change in the sound pressure level (decibel) of audio data output from the digital amplifier 191 when the system volume is fixed while the switch volume is changed. In FIG. 14, the horizontal axis represents the switch volume, and the vertical axis indicates the sound pressure level. The bottommost line in FIG. 14 indicates the sound pressure level when the system volume is 1, and the second line from the bottommost line designates the sound pressure level when the system volume is 2. Similarly, the topmost line indicates the sound pressure level when the system volume is 19. Thus, different initial sound pressure levels depending on the system volumes are set, and the sound pressure level changes with respect to the switch volume with almost the same gradient regardless of the system volume.

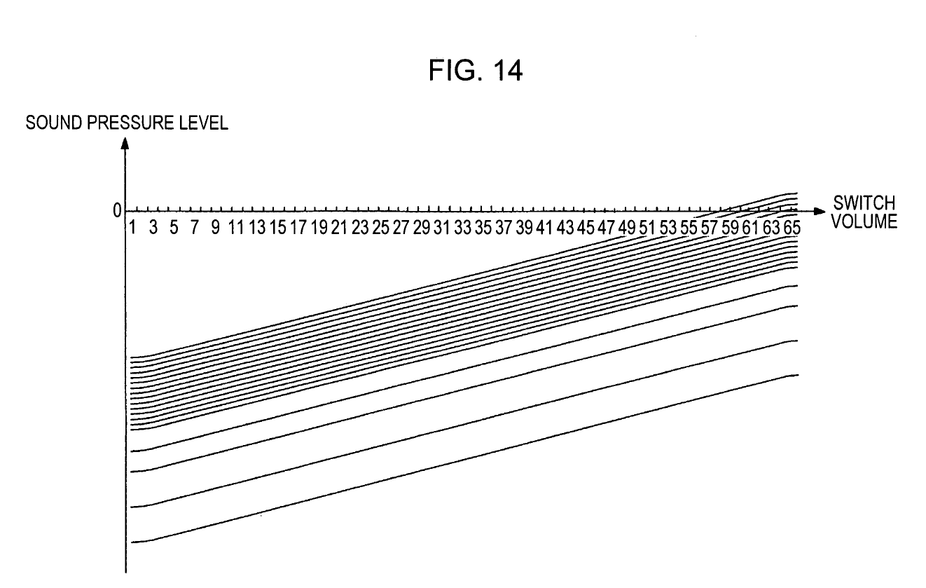

FIG. 15 illustrates a change in the sound pressure level (decibel) of audio data output from the digital amplifier 191 when the switch volume is fixed while the system volume is changed. In FIG. 15, the horizontal axis represents the system volume, and the vertical axis designates the sound pressure level. The bottommost line in FIG. 15 indicates the sound pressure level when the switch volume is 000001 in binary format, and the second line from the bottommost line designates the sound pressure level when the switch volume is 000010 in binary format. Similarly, the topmost line indicates the sound pressure level when the switch volume is 111111. Thus, different initial sound pressure levels depending on the switch volumes are set, and the sound pressure level changes with respect to the system volume with almost the same gradient regardless of the switch volume.

As is seen from FIGS. 14 and 15, the user can set the sound pressure level of audio data supplied from the digital amplifier 191 by changing the switch volume by operating the volume switch 193 of the APR 112 or by changing the system volume by using the system volume setting function of the OS 224 or operating the volume button 157. Thus, the user can set the volume of the output sound of the loudspeaker 192 of the APR 112.

In step S116 of FIG. 13, the volume controller 244 transforms the mantissa pointer into actual mantissa data. More specifically, the volume controller 244 separates the gain calculated value obtained in step S115 into the exponent data and the mantissa pointer, and transforms the mantissa pointer into the mantissa data to which the mantissa pointer is assigned.

In step S117, the volume controller 244 stores the volume gain obtained in step S113 or the volume gain calculated in steps S114 through S116, and the volume gain calculating processing is completed.

As described above, in the information processing system 101, a total of 1198 levels (19-level system volumes×63-level switch volumes+a one-level volume when the switch volume or the system volume is 0) of volumes (volume gains) of the loudspeaker 192 of the APR 112 can be set.

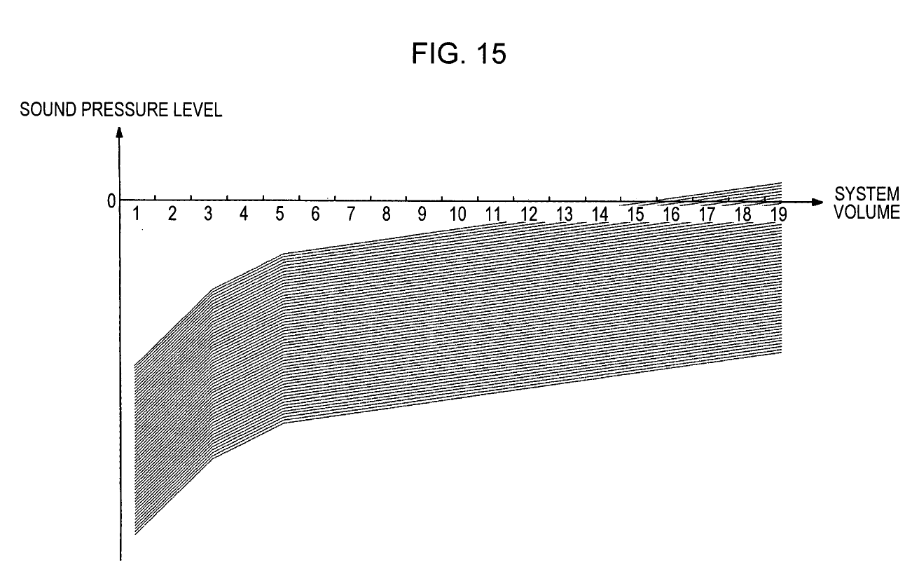

FIG. 16 is a table indicating the relationships between the difference of the calculation methods for the gains and the resulting performance of the information processing system 101. More specifically, in the second column of the table, all the 1198-level volume gains are stored as the table values in advance, and the volume gains are set only by referring to the table values (using only table values). In the third column of the table, data required for calculating the volume gains are stored as the table values and the volume gains are calculated based on the table values (using table values and calculations). In the fourth column of the table, the volume gains are determined only by calculations (using only calculations).

The memory capacity required for storing fixed data (table values) for calculating the volume gains is first considered. In this case, a memory which is temporarily necessary while calculating the volume gains is not considered. When using only the table values, the volume gains are stored. In this case, they are stored in units of two bytes in the memory although they are actually 13-bit data, and the required memory capacity results in 2396 bytes (two bytes×1198 levels). When using only calculations, the required memory capacity results in 0.

When using the table values and calculations, the 19 reference gain calculated values, the 8 mantissa data, and the volume gain when the system volume is 0 or the switch volume is 0 are stored in the memory. Although the reference gain calculated values are 8 bits (one byte) and the mantissa data is 5 bits, they are stored in units of bytes in the memory. Although the volume gain when the system volume is 0 or the switch volume is 0 is 13 bits, it is stored in units of two bytes in the memory. Accordingly, the required memory capacity results in 29 bytes (one byte×19 reference gain calculated values+one byte×8 mantissa data, and two bytes). Thus, when using the table values and calculations, the required memory capacity is much smaller than when using only the table values, and is almost equivalent to when using only calculations.

The CPU load when the volume gains are calculated is now considered. When using only the table values, the volume gains are merely selected from the table values, and thus, the CPU load is very low. When using only calculations, the volume gains should be calculated from scratch, and thus, the CPU load is very high. When using the table values and calculations, the calculations required for determining the volume gains are merely an addition of the reference gain volumes and the switch volume. Thus, the CPU load can be reduced to a minimal level as when using only the table values.

Finally, the maintainability for adjusting the volume gains is considered. When using only the table values, it is necessary to modify all the table values of the 1198-level volume gains, and thus, the maintainability is very low. When using only calculations, it is necessary to modify computation expressions and to overwrite programs, and thus, the maintainability is an intermediate level. When using the table values and calculations, the volume gains can be adjusted by modifying only the reference gain calculated values and mantissa data. Thus, the maintainability is very high.

Thus, according to the volume gain calculation method used in the information processing system 101, the required memory capacity is small, the CPU load when calculating the volume gains is low, and the volume gain can be easily adjusted (high maintainability).

The APR volume setting processing performed by the embedded controller 155 executing the EC firmware 221 is described below with reference to the flowchart of FIG. 17. This processing is performed at regular intervals, for example, 15 ms, when the personal computer 111 is powered ON.

In step S131, the port replicator connection detector 42 determines whether the APR 112 is connected to the personal computer 111, as in step S1 of FIG. 8. If it is determined that the APR 112 is connected, the process proceeds to step S132.

In step S132, the digital amplifier controller 247 determines whether the digital amplifier 191 of the APR 112 has been initialized, as in step S2 of FIG. 8. If it is determined that the digital amplifier 191 has been initialized, the process proceeds to step S133.

In step S133, the volume controller 244 determines whether the right-and-left common volume calculated flag is ON. If the right-and-left common volume calculated flag is found to be ON, i.e., if the right-and-left common volume calculated flag is turned ON in step S85 of FIG. 12, the process proceeds to step S134.

In step S134, the volume controller 244 sets the volume gain stored in step S117 of FIG. 13 as the right-and-left common volume gain. More specifically, the volume controller 244 sets the stored volume gain as the right-and-left common volume gain, and supplies the volume gain data indicating the set volume gain to the digital amplifier controller 247.

In step S135, the volume controller 244 turns OFF the right-and-left common volume calculated flag, and the process proceeds to step S142.

If it is determined in step S133 that the right-and-left common volume calculated flag is OFF, the process proceeds to step S136 to determine whether the left volume calculated flag is ON. If the left volume calculated flag is found to be ON, i.e., if the left volume calculated flag is turned ON in step S89 of FIG. 12, the process proceeds to step S137.

In step S137, the volume controller 244 sets the volume gain stored in step S117 of FIG. 13 to be the left volume gain. More specifically, the volume controller 244 sets the stored volume gain to be the left volume gain, and supplies the volume gain data indicating the set volume gain to the digital amplifier controller 247.

In step S138, the volume controller 244 turns OFF the left volume calculated flag, and the process proceeds to step S142.

If it is determined in step S136 that the left volume calculated flag is OFF, the process proceeds to step S139 to determine whether the right volume calculated flag is ON. If the right volume calculated flag is found to be ON, i.e., the right volume calculated flag is turned ON in step S93 of FIG. 12, the process proceeds to step S140.

In step S140, the volume controller 244 sets the volume gain stored in step S117 of FIG. 13 as the right volume gain. More specifically, the volume controller 244 sets the stored volume gain as the right volume gain, and supplies the volume gain data indicating the set volume gain to the digital amplifier controller 247.

In step S141, the volume controller 244 turns OFF the right volume calculated flag, and the process proceeds to step S142.

In step S142, the digital amplifier controller 247 supplies the volume gain data to the digital amplifier 191, and the APR volume setting processing is completed. Then, the digital amplifier 191 drives the loudspeaker 192 with the volume gain indicated in the volume gain data based on the volume data supplied from the audio data processor 160. Then, the volume of the output sound from the loudspeaker 192 can be changed.

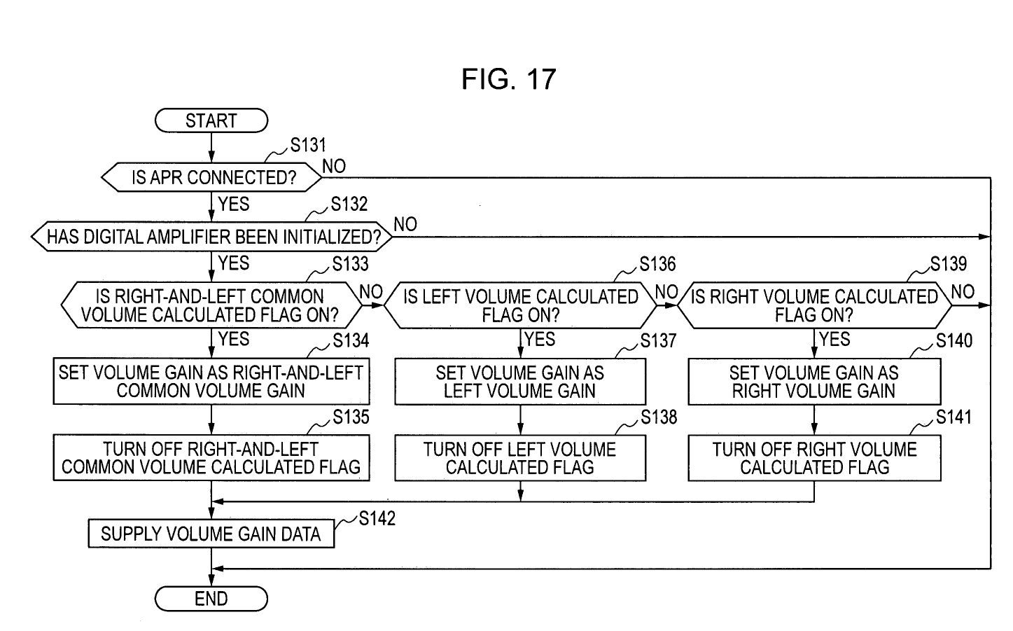

Initializing processing performed by the embedded controller 155 executing the EC firmware 221 when the personal computer 101 is powered ON is discussed below with reference to the flowchart of FIG. 18.

In step S161, the volume controller 244 determines whether the right system volume and the left system volume are independently set, as in step S14 of FIG. 9. If it is determined that the right and left system volumes are not independently set, the process proceeds to step S162.

In step S162, the volume controller 244 turns ON the right-and-left common volume change flag, and the initializing processing is completed.

If it is determined in step S161 that the right and left system volumes are independently set, the process proceeds to step S163. In step S163, the volume controller 244 turns ON the right volume change flag and the left volume change flag, and the initializing processing is completed.

In this initializing processing, the right-and-left common volume change flag, the right volume change flag, or the left volume change flag is turned ON. Thus, the volume gain of the digital amplifier 191 of the APR 112 can be calculated in the APR volume calculating processing shown in FIG. 12.

Mute processing performed by the information processing system 101 is described below with reference to FIGS. 19 through 37.

A description is first given, with reference to FIGS. 19 through 22, of the relationship between the mute setting of the information processing system 101 and the sound output state.

In the information processing system 101, the mute setting can be turned ON or OFF to stop or start outputting sound. FIG. 19 illustrates a transition of the mute setting condition. In a condition 301, the mute setting of the information processing system 101 is OFF. In a condition 302, the mute setting of the information processing system 101 is ON.

In the condition 301, sound is output, and the LED 159, which indicates the mute setting condition, is OFF. That is, when the mute setting is OFF, sound is output from the information processing system 101. When the user presses the mute button 158 or turns ON the mute setting by using the mute setting function of the OS 224 directly or via the application program 225, the information processing system 101 is shifted from the condition 301 to the condition 302.

In the condition 302, sound is not output, and the LED 159, which indicates the mute setting condition, is ON. That is, when the mute setting is ON, sound is not output from the information processing system 101. When the user presses the mute button 158 or turns OFF the mute setting by using the mute setting function of the OS 224 directly or via the application program 225, the information processing system 101 is shifted from the condition 302 to the condition 301.

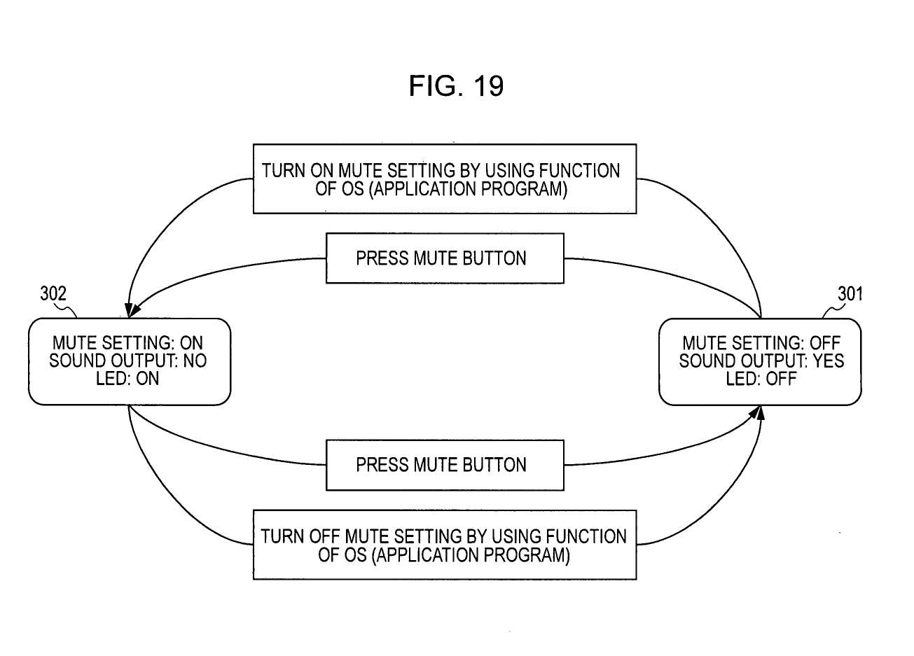

FIG. 20 is a table illustrating the sound output states of the information processing system 101. The numbers indicated in the first column of the table represent line numbers.

The second column of the table shown in FIG. 20 indicates the connecting state of the information processing system 101. In line numbers 1 and 2, “only PC” means that none of the APR 112, the BPR 113, and a headphone is connected to the personal computer 111. In line numbers 3 and 4, “PC+HP” means that a headphone is connected to the analog sound output unit 163 of the personal computer 101. In line numbers 5 and 6, “PC+BPR” means that the BPR 113 is connected to the personal computer 111.

In line numbers 7 and 8, “PC+BPR+HP” means that the BPR 113 is connected to the personal computer 111 and also a headphone is connected to the analog sound output unit 163 of the personal computer 101. In line numbers 9 and 10, “PC+APR” indicates that the APR 112 is connected to the personal computer 111. In line numbers 11 and 12, “PC+APR+HP” indicates that the APR 112 is connected to the personal computer 111 and also a headphone is connected to the analog sound output unit 163 of the personal computer 111.

The third column of the table shown in FIG. 20 represents the mute setting condition. As in line number 1, “OFF” means that the mute setting of the information processing system 101 is OFF. As in line number 2, “ON” means that the mute setting of the information processing system 101 is ON.

The fourth through sixth columns of the table represent the sound output states of the information processing system 101. The fourth column of the table indicates the sound output state of the built-in loudspeaker 162 of the personal computer 111. The fifth column designates the sound output state of the loudspeaker 192 of the APR 112. The sixth column represents the sound output state of the headphone connected to the analog sound output unit 163 of the personal computer 101. In the fourth through sixth columns, “unmute” indicates that sound is output, and “mute” indicates that sound is not output.

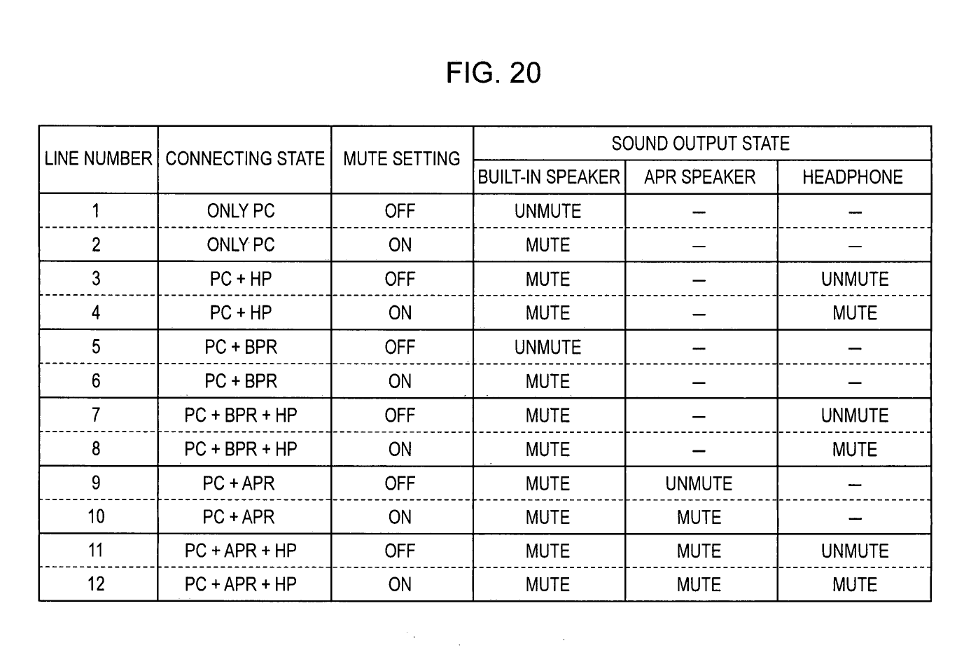

FIG. 21 illustrates a transition of the sound output state when the mute setting of the information processing system 101 is OFF. In a condition 311, neither of a port replicator nor a headphone is connected to the personal computer 111 (connecting state of line number 1 in FIG. 20), or the BPR 113 is connected to the personal computer (connecting state of line number 5 in FIG. 20). In the condition 311, sound is output from the built-in loudspeaker 162, and the LED 159 is OFF.

In a condition 312, the APR 112 is connected to the personal computer 111 (connecting state of line number 9 in FIG. 20). In the condition 312, the sound is output from the loudspeaker 192 of the APR 112 and is not output from the built-in loudspeaker 162. The LED 159 is OFF.

In a condition 313, the APR 112 is connected to the personal computer 111, and a headphone is connected to the analog sound output unit 163 of the personal computer 111 (connecting state of line number 11 in FIG. 20). In the condition 313, sound is output from the headphone connected to the analog sound output unit 163 and is not output from the built-in loudspeaker 162 and the loudspeaker 192 of the APR 112. The LED 159 is OFF.

In a condition 314, a headphone is connected to the analog sound output unit 163 of the personal computer 111 (connecting state of line number 3 in FIG. 20), or the BPR 113 is connected to the personal computer 11 and a headphone is connected to the analog sound output unit 163 of the personal computer 111 (connecting state of line number 7 in FIG. 20). In the condition 314, sound is output from the headphone connected to the analog sound output unit 163 and is not output from the built-in loudspeaker 162. The LED 159 is OFF.

In the condition 311, even if the BPR 113 is connected (installed) or removed to or from the personal computer 111, the sound output state remains the same. If the APR 112 is connected to the personal computer 111 in the condition 311, the sound output state is shifted to the condition 312. If a headphone is connected to the analog sound output unit 163 of the personal computer 111, the sound output state is shifted to the condition 314. If the mute setting of the information processing system 101 is turned ON, the sound output state is shifted to a condition 321 of FIG. 22, which is discussed below.

In the condition 312, if a headphone is connected to the analog sound output unit 163 of the personal computer 111, the sound output state is shifted to the condition 313. If the APR 112 is removed from the personal computer 111, the sound output state is shifted to the condition 311. If the mute setting of the information processing system 101 is turned ON, the sound output state is shifted to a condition 322 of FIG. 22, which is discussed below.

In the condition 313, if the headphone is removed from the analog sound output unit 163 of the personal computer 111, the sound output state is shifted to the condition 312. If the APR 112 is removed from the personal computer 111, the sound output state is shifted to the condition 314. If the mute setting of the information processing system 101 is turned ON, the sound output state is shifted to a condition 323 of FIG. 22, which is discussed below.

In the condition 314, even if the BPR 113 is connected or removed to or from the personal computer 111, the sound output state remains the same. If the APR 112 is connected to the personal computer 111, the sound output state is shifted to the condition 313. If the headphone is removed from the analog sound output unit 163 of the personal computer 111, the sound output state is shifted to the condition 311. If the mute setting of the information processing system 101 is turned ON, the sound output state is shifted to a condition 324 of FIG. 22, which is discussed below.

FIG. 22 illustrates a transition of the sound output state when the mute setting of the information processing system 101 is ON. In the condition 321, neither of a port replicator nor a headphone is connected to the personal computer 111 (connecting state of line number 2 in FIG. 20), or the BPR 113 is connected to the personal computer 111 (connecting state of line number 6 in FIG. 20). In the condition 311, sound is not output from the built-in loudspeaker 162. The LED 159 is ON.

In the condition 322, the APR 112 is connected to the personal computer 111 (connecting state of line number 10 in FIG. 20). In the condition 322, sound is not output from the loudspeaker 192 of the APR 112 or the built-in loudspeaker 162. The LED 159 is ON.

In the condition 323, the APR 112 is connected to the personal computer 111 and a headphone is connected to the analog sound output unit 163 of the personal computer 111 (connecting state of line number 12 in FIG. 20). In the condition 323, sound is not output from the headphone connected to the analog sound output unit 163, the built-in loudspeaker 162, or the loudspeaker 192 of the APR 112. The LED 159 is ON.

In the condition 324, a headphone is connected to the analog sound output unit 163 of the personal computer 111 (connecting state of line number 4 in FIG. 20), or the BPR 113 is connected to the personal computer 111 and a headphone is connected to the analog sound output unit 163 of the personal computer 101 (connecting state of line number 8 in FIG. 20). In the condition 324, sound is not output from the headphone connected to the analog sound output unit 163 or the built-in loudspeaker 162. The LED 159 is ON.

In the condition 321, even if the BPR 113 is connected or removed to or from the personal computer 111, the sound output state remains the same. In the condition 321, if the APR 112 is connected to the personal computer 111, the sound output state is shifted to the condition 322. If a headphone is connected to the analog sound output unit 163 of the personal computer 111, the sound output state is shifted to the condition 324. If the mute setting of the information processing system 101 is turned OFF, the sound output state is shifted to the condition 311 in FIG. 21.

In the condition 322, if a headphone is connected to the analog sound output unit 163 of the personal computer 111, the sound output state is shifted to the condition 323. If the APR 112 is removed from the personal computer 111, the sound output state is shifted to the condition 321. If the mute setting of the information processing system 101 is turned OFF, the sound output state is shifted to the condition 312 in FIG. 21.

In the condition 323, if the headphone is removed from the analog sound output unit 163 of the personal computer 111, the sound output state is shifted to the condition 322. If the APR 112 is removed from the personal computer 111, the sound output state is shifted to the condition 324. If the mute setting of the information processing system 101 is turned OFF, the sound output state is shifted to the condition 313 in FIG. 21.

In the condition 324, even if the BPR 113 is connected or removed to or from the personal computer 111, the sound output state remains the same. If the APR 112 is connected to the personal computer 111, the sound output state is shifted to the condition 323. If the headphone is removed from the analog sound output unit 163 of the personal computer 111, the sound output state is shifted to the condition 321. If the mute setting of the information processing system 101 is turned OFF, the sound output state is shifted to the condition 314 in FIG. 21.

The mute processing performed by the information processing system 101 to implement the above-described transition of the sound output state is discussed below.

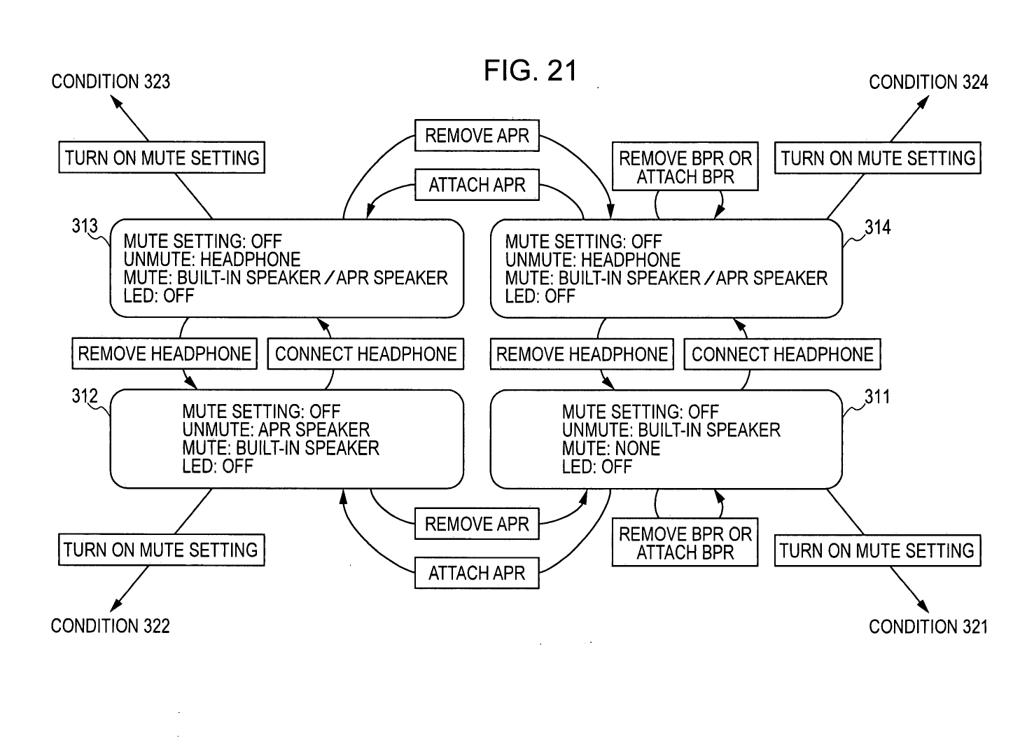

A description is first given, with reference to FIGS. 23 through 28, of the mute processing performed by the information processing system 101 by operating the mute button 158.

Mute button polling processing performed by the embedded controller 155 executing the EC firmware 221 is first described below with reference to the flowchart of FIG. 23. This processing is performed at regular intervals, for example, 5 ms, when the personal computer 101 is powered ON.

In step S201, the mute controller 245 detects the condition of the mute button 158. If the user has pressed the mute button 158, a mute button signal is supplied to the mute controller 245 from the mute button 158 via the hardware signal input unit 241. The mute controller 245 detects whether the mute button signal has been supplied.

In step S202, the mute controller 245 determines whether the condition of the mute button 158 has been changed. More specifically, if the mute controller 245 determines based on the result of step S201 that the condition of the mute button 158 has been changed by comparing the supply state of the mute button signal with that of the previous mute button polling processing, i.e., that the supply of the mute button signal is started or stopped, the process proceeds to step S203.

In step S203, the mute controller 245 sets the timer, and the mute button polling processing is completed. If the timer has already been set, the mute controller 245 resets the timer by changing the timer value to be 0.

If it is determined in step S202 that the condition of the mute button 158 has not been changed, the process proceeds to step S204 to determine whether the timer is set. If the timer is set, the process proceeds to step S205.

In step S205, the mute controller 245 updates the timer.

In step S206, the mute controller 245 determines whether the timer has reached a predetermined time. If the timer has reached the predetermined time, i.e., if the mute button 158 has been changed longer than or equal to the predetermined time (for example, 100 ms) of the timer after it is determined in step S202 in the previous mute button polling processing that the condition of the mute button 158 was changed, the process proceeds to step S207. Because of this processing, it is possible to prevent erroneous detection of the condition of the mute button 158 caused by chattering (vibrations) when the mute button 158 is pressed.

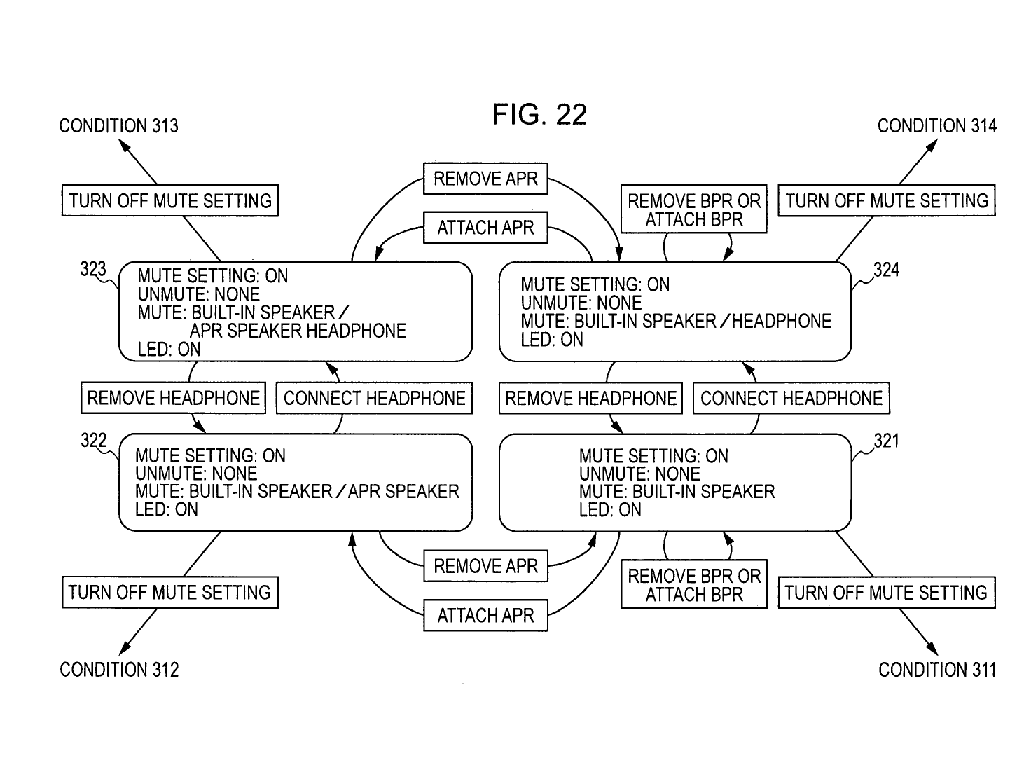

In step S207, the embedded controller 255 performs mute condition setting processing. In this processing, the mute condition of the information processing system 101 is changed. Details of the mute condition setting processing are given below with reference to FIG. 24.

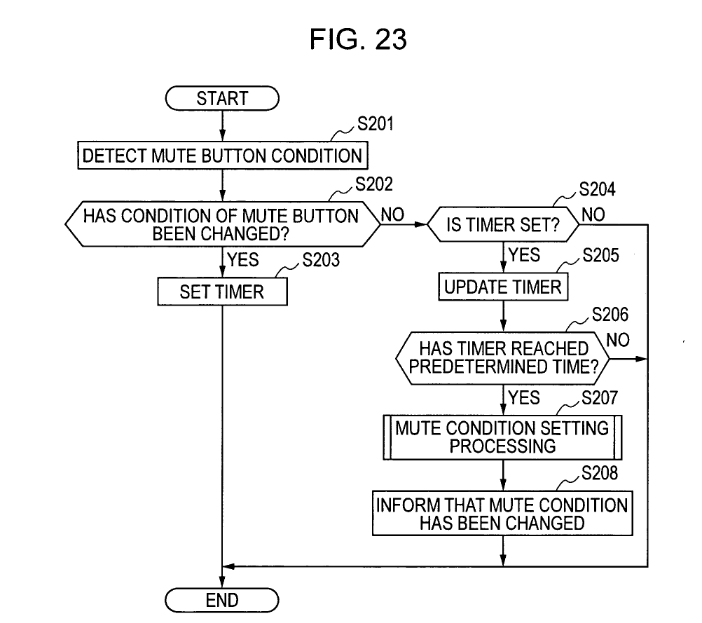

In step S208, the mute controller 245 informs the utility program 226 that the mute condition has been changed, and the mute button polling processing is completed. More specifically, the mute controller 245 supplies mute setting changing information to the utility program 226 via the utility communication unit 246. The utility program 226 receives the mute setting changing information in step S241 of FIG. 25, which is discussed later.

If it is determined in step S206 that the timer has not reached the predetermined time, i.e., that the condition of the mute button 158 has not been changed longer than or equal to the predetermined time of the timer after it is determined in step S202 in the previous mute button polling processing that the condition of the mute button 158 was changed, steps S207 and S208 are skipped, and the mute button polling processing is completed.

If it is determined in step S204 that the timer is not set, steps S205 through S208 are skipped, and the mute button polling processing is completed.

Details of the mute condition setting processing in step S207 of FIG. 23 are discussed below with reference to the flowchart of FIG. 24.

In step S221, the mute controller 245 determines whether the mute button 158 has been pressed. If it is determined that the mute button 158 has been pressed, i.e., if a mute button signal is supplied to the mute controller 245 via the hardware signal input unit 241, the process proceeds to step S222.

In step S222, the port replicator connection detector 242 determines whether the APR 112 is connected, as in step S1 of FIG. 8. If it is determined that the APR 112 is connected, the process proceeds to step S223.

In step S223, the mute controller 245 changes the mute condition of the personal computer 111. More specifically, if the mute setting flag is ON, i.e., if the mute setting of the information processing system 101 is ON, the mute controller 245 stops supplying a mute signal to the analog amplifier 161. Then, the analog amplifier 161 starts supplying an audio signal to the built-in loudspeaker 162 or the analog sound output unit 163. The mute controller 245 turns OFF the mute setting flag.

Conversely, if the mute setting flag is OFF, i.e., if the mute setting of the information processing system 101 is OFF, the mute controller 245 starts supplying a mute signal to the analog amplifier 161. Then, the analog amplifier 161 stops supplying an audio signal to the built-in loudspeaker 162 and the analog sound output unit 163. The mute controller 245 turns ON the mute setting flag.

Supplying a mute signal to the analog amplifier 161 and stopping the output of an audio signal to the built-in loudspeaker 162 and the analog sound output unit 163 from the analog amplifier 161 by the mute controller 245 is hereinafter referred to as “setting the personal computer 111 in the mute state”. That is, when the personal computer 111 is in the mute state, sound is not output from the built-in loudspeaker 162 and the analog sound output unit 163.

In contrast, stopping the supply of a mute signal to the analog amplifier 161 and starting to output an audio signal to the built-in loudspeaker 162 or the analog sound output unit 163 from the analog amplifier 161 by the mute controller 245 is hereinafter referred to as “canceling the mute state of the personal computer 111” or “setting the personal computer 111 in the unmute state”. When the personal computer 111 is in the unmute state, sound is output from the built-in loudspeaker 162 when an external audio unit is not connected to the analog sound output unit 163. When an external audio unit is connected to the analog sound output unit 163, sound is output from the external audio unit via the analog sound output unit 163.

Supplying a mute signal to the digital amplifier 191 and stopping the output of an audio signal to the loudspeaker 192 from the digital amplifier 191 by the mute controller 245 is hereinafter referred to as “setting the APR 112 in the mute state”. That is, when the APR 112 is in the mute state, sound is not output from the loudspeaker 192. In contrast, stopping the supply of a mute signal to the digital amplifier 191 and starting to output an audio signal to the loudspeaker 192 from the digital amplifier 191 by the mute controller 245 is hereinafter referred to as “canceling the mute state of the APR 112” or “setting the APR 112 in the unmute state”. When the APR 112 is in the unmute state, sound is output from the loudspeaker 192 of the APR 112.

In step S223, the mute controller 245 supplies mute setting information to the display controller 248.

In step S224, the display controller 248 synchronizes the condition of the LED 159 with the mute setting of the information processing system 101, and the mute condition setting processing is then completed. More specifically, if the mute setting information indicates that the mute setting of the information processing system 101 is ON, the display controller 248 turns ON the LED 159. If the mute setting information indicates that the mute setting is OFF, the display controller 248 turns OFF the LED 159.

If it is determined in step S222 that the APR 112 is connected, the process proceeds to step S225.

In step S225, the digital amplifier controller 247 determines whether the digital amplifier 191 has been initialized, as in step S2 of FIG. 8. If it is determined that the digital amplifier 191 has been initialized, the process proceeds to step S226.

In step S226, the mute controller 245 changes the mute condition of the personal computer 111 and the APR 112.

More specifically, if the mute setting flag is OFF and if an audio-unit connecting signal is not supplied from the analog amplifier 161, i.e., if the mute setting of the information processing system 101 is OFF and if an external audio unit, for example, a headphone, is not connected to the analog sound output unit 163, the mute controller 245 sets the APR 112 in the mute state. The mute controller 245 also turns ON the mute setting flag.

If the mute setting flag is OFF and if an audio-unit connecting signal is supplied from the analog amplifier 161, the mute controller 245 sets the personal computer 111 in the mute state. The mute controller 245 also turns ON the mute setting flag.

If the mute setting flag is ON and if an audio-unit connecting signal is not supplied from the analog amplifier 161, the mute controller 245 cancels the mute state of the APR 112. The mute controller 245 also turns OFF the mute setting flag.

If the mute setting flag is ON and if an audio-unit connecting signal is supplied from the analog amplifier 161, the mute controller 245 cancels the mute state of the personal computer 111. The mute controller 245 also turns OFF the mute setting flag.

Also in step S226, the mute controller 245 supplies mute setting information to the display controller 248.

In step S227, the display controller 248 synchronizes the condition of the LED 159 with the mute setting of the information processing system 101, as in step S224, and the mute condition setting processing is then completed.

If it is determined in step S225 that the digital amplifier 191 has not been initialized, the mute condition setting processing is terminated.

If it is determined in step S221 that the mute button 158 has not been pressed, the mute setting condition processing is terminated.

The processing shown in FIGS. 23 and 24 can be performed only by the execution of the embedded controller 155 without using the CPU 151 (OS 224). Thus, the user can change the mute setting of the information processing system 101 by operating the mute button 158 even if the OS 224 is not operated.

A description is now given, with reference to the flowchart of FIG. 25, of mute setting query processing by the CPU 151 executing the utility program 226 in association with the mute button polling processing by the embedded controller 155 shown in FIG. 23.

In step S241, the utility program 226 receives the mute setting changing information supplied from the mute controller 245 in step S208 of FIG. 23.

In step S242, the utility program 226 queries the mute controller 245 as to the mute setting condition of the information processing system 101. More specifically, the utility program 226 supplies mute setting query information to the mute controller 245 via the utility communication unit 246.

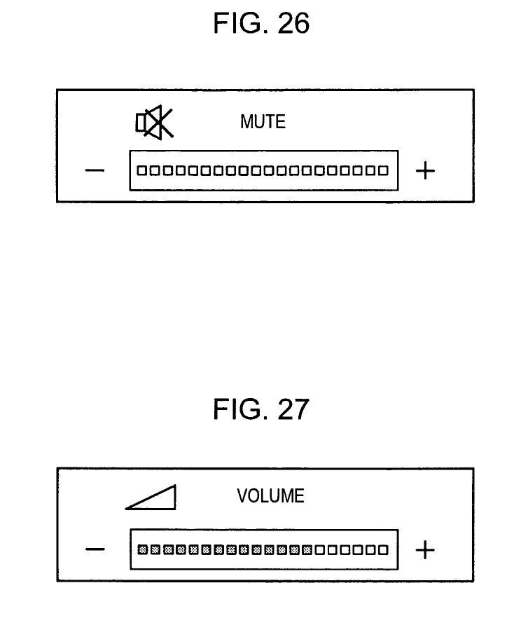

In step S261 of FIG. 28, which is discussed below, the mute controller 245 receives the mute setting query information, and supplies mute setting information in step S262.

In step S243, the utility program 226 receives the mute setting information from the mute controller 245 via the utility communication unit 246.

In step S244, the utility program 226 displays a dialog. More specifically, when the mute setting information indicates that the mute setting of the information processing system 101 is ON, the utility program 226 displays the dialog shown in FIG. 26 on the display unit 164. When the mute setting information indicates that the mute setting is OFF, the utility program 226 displays the dialog shown in FIG. 27 on the display unit 164.

In step S245, the utility program 226 informs the OS 224 that the mute setting has been changed, and the mute setting query processing is completed. This enables the OS 224 to identify that the mute setting has been changed by the mute button 158, and can display the actual mute setting condition.

A description is now given, with reference to the flowchart of FIG. 28, of mute setting query response processing by the embedded controller 155 executing the EC firmware 221 in association with the mute setting query processing by the utility program 226 shown in FIG. 25.

In step S261, the mute controller 245 receives the mute setting query information supplied from the utility program 226 in step S242 of FIG. 25.

In step S262, the mute controller 245 supplies the mute setting information to the utility program 226 via the utility communication unit 246, and the mute setting query response processing is completed.

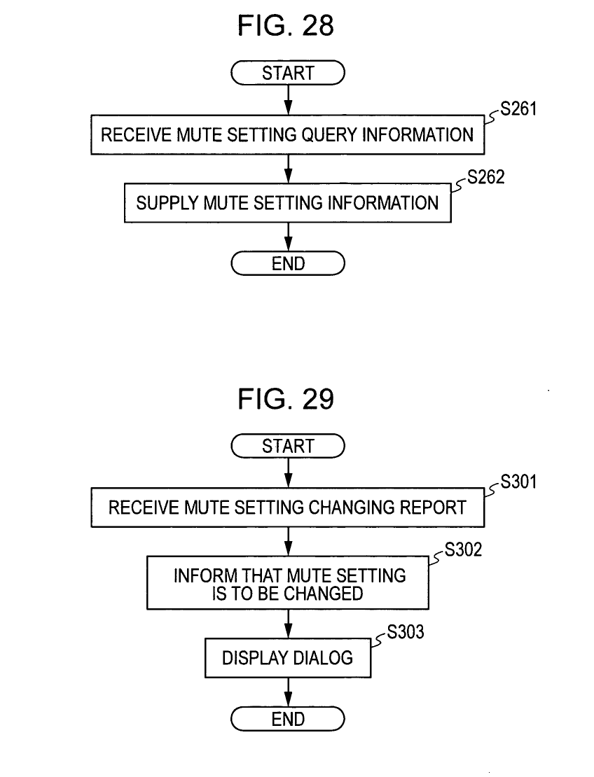

The mute processing by the information processing system 101 by using the mute setting function of the OS 224 is described below with reference to FIGS. 29 through 31.

Mute setting changing information receiving processing by the CPU 151 executing the utility program 226 is first discussed with reference to the flowchart of FIG. 29.

When the user change the mute setting of the information processing system 101 by using the function of the OS 224, mute setting changing information is supplied to the utility program 226 from the OS 224.

In step S301, the utility program 226 receives the mute setting changing information from the OS 224.

In step S302, the utility program 226 informs the mute controller 245 that the mute setting is to be changed. More specifically, if the mute setting changing information indicates that an instruction is given by the OS 224 to turn ON the mute setting, the utility program 226 supplies mute setting instruction information to the mute controller 245 via the utility communication unit 246. If an instruction is given by the OS 224 to turn OFF the mute setting, the utility program 226 supplies unmute setting instruction information to the mute controller 245 via the utility communication unit 246.

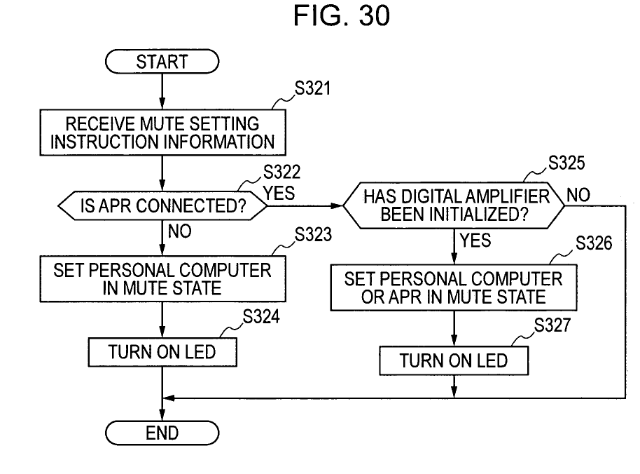

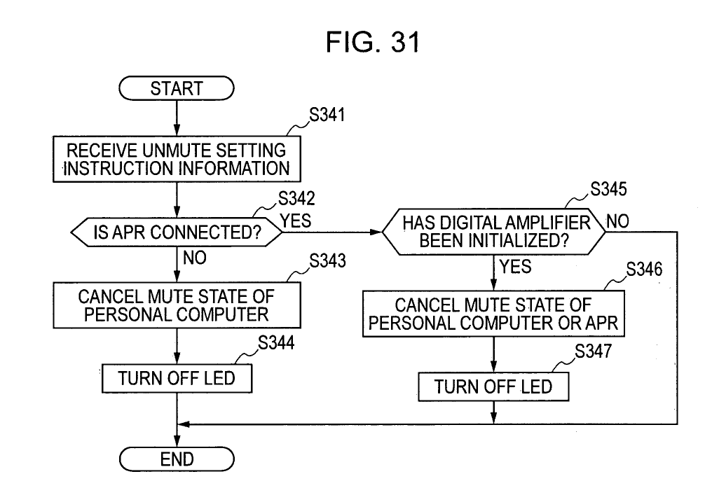

If the mute setting instruction information is supplied from the utility program 226, the mute controller 245 receives the mute setting instruction information in step S321 of FIG. 30, which is discussed below. If the unmute setting instruction information is supplied from the utility program 226, the mute controller 245 receives the unmute setting instruction information in step S341 of FIG. 31, which is discussed below.

In step S303, the utility program 226 displays a dialog on the display unit 164, as in step S244 of FIG. 25, and the mute setting changing information receiving processing is then completed.

A description is now given, with reference to the flowchart of FIG. 30, of mute setting instruction information receiving processing by the embedded controller 155 executing the EC firmware 221 in association with the mute setting changing information receiving processing by the utility program 226 shown in FIG. 29.

In step S321, the mute controller 245 receives the mute setting instruction information supplied from the utility program 226 in step S302 of FIG. 29 via the utility communication unit 246.

In step S322, the port replicator connection detector 242 determines whether the APR 112 is connected to the personal computer 111, as in step S1 of FIG. 8. If it is determined that the APR 112 is not connected, the process proceeds to step S323.

In step S323, the mute controller 245 sets the personal computer 111 in the mute state, and turns ON the mute setting flag. The mute controller 245 also supplies mute setting information to the display controller 248.

In step S324, the display controller 248 turns ON the LED 159, and the mute setting instruction information receiving processing is completed.

If it is determined in step S322 that the APR 112 is connected, the process proceeds to step S325.

In step S325, the digital amplifier controller 247 determines whether the digital amplifier 191 of the APR 112 has been initialized, as in step S2 of FIG. 8. If it is determined that the digital amplifier 191 has been initialized, the process proceeds to step S326.

In step S326, the mute controller 245 sets the personal computer 111 or the APR 112 in the mute state. More specifically, if an audio-unit connecting signal is not input form the analog amplifier 161, i.e., if an external audio unit, such as a headphone, is not connected to the analog sound output unit 163, the mute controller 245 sets the APR 112 in the mute state. If an audio-unit connecting signal is input from the analog amplifier 161, i.e., if an external audio unit, such as a headphone, is connected to the analog sound output unit 163, the mute controller 245 sets the personal computer 111 in the mute state. The mute controller 245 turns ON the mute setting flag, and supplies mute setting information to the display controller 248.

In step S327, the display controller 248 turns ON the LED 159, and the mute setting instruction information receiving processing is completed.

If it is determined in step S325 that the digital amplifier 191 has not been initialized, the mute setting instruction information receiving processing is terminated.

A description is now given, with reference to the flowchart of FIG. 31, of unmute setting instruction information receiving processing by the embedded controller 155 executing the EC firmware 221 in association with the mute setting changing information receiving processing by the utility program 226 in FIG. 29.

In step S341, the mute controller 245 receives the unmute setting instruction information supplied from the utility program 226 in step S302 of FIG. 29.

In step S342, the port replicator 242 determines whether the APR 112 is connected to the personal computer 111, as in step S1 of FIG. 8. If the APR 112 is not connected, the process proceeds to step S343.

In step S343, the mute controller 245 cancels the mute state of the personal computer 111, and turns OFF the mute setting flag. The mute controller 245 also supplies mute setting information to the display controller 248.

In step S344, the display controller 248 turns OFF the LED 159, and the unmute setting instruction information receiving processing is then completed.

If it is determined in step S342 that the APR 112 is connected, the process proceeds to step S345.

In step S345, the digital amplifier controller 247 determines whether the digital amplifier 191 of the APR 112 has been initialized, as in step S2 of FIG. 8. If it is determined that the digital amplifier 191 has been initialized, the process proceeds to step S346.

In step S346, the mute controller 245 cancels the mute state of the personal computer 111 or the APR 112. More specifically, if an audio-unit connecting signal is not input from the analog amplifier 161, i.e., if an external audio unit, such as a headphone, is not connected to the analog sound output unit 163, the mute controller 245 cancels the mute state of the APR 112.

If an audio-unit connecting signal is input from the analog amplifier 161, i.e., if an external audio unit, such as a headphone, is connected to the analog sound output unit 163, the mute controller 245 cancels the mute state of the personal computer 111.

The mute controller 245 also turns OFF the mute setting flag, and supplies the mute setting information to the display controller 248.

In step S347, the display controller 248 turns OFF the LED 159, and the unmute setting instruction information receiving processing is completed.

If it is determined in step S345 that the digital amplifier 191 has not been initialized, the unmute setting instruction information receiving processing is terminated.

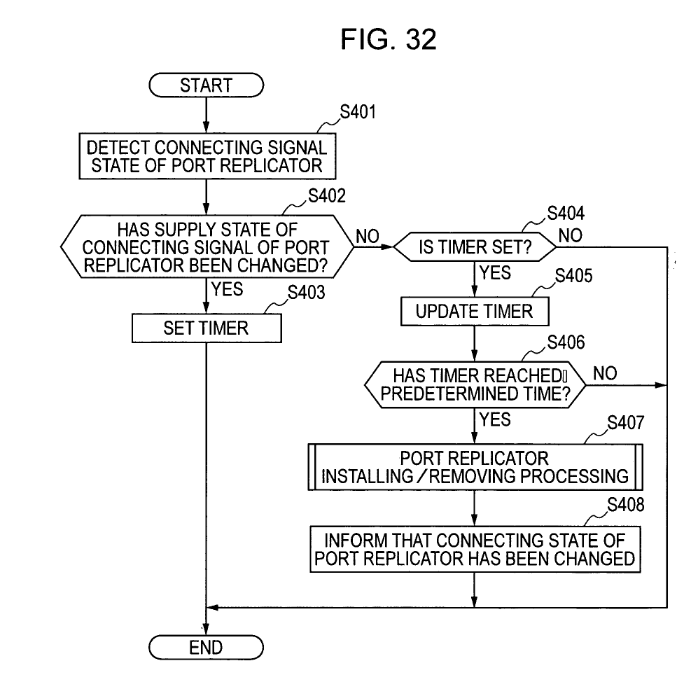

A description is now given, with reference to FIGS. 32 through 35, of mute processing by the information processing system 101 when a port replicator is connected (installed) or removed to or from the personal computer 111.

Port replicator installing/removing detection processing by the embedded controller 155 executing the EC firmware 221 is discussed first with reference to the flowchart of FIG. 32. This processing is performed at regular intervals, for example, 5 ms, when the personal computer 111 is powered ON.

In step S401, the port replicator connection detector 242 of the embedded controller 155 detects the state of a port replicator connecting signal. More specifically, if the APR 112 is connected to the personal computer 111, an APR connecting signal is supplied from the connecting signal output unit 121 of the APR 112 via the hardware signal input unit 241. If the BPR 113 is connected to the personal computer 111, a BPR connecting signal is supplied from the connecting signal output unit 131 of the BPR 113 via the hardware signal input unit 241. The port replicator connection detector 242 determines whether the APR connecting signal or the BPR connecting signal is supplied.

In step S402, the port replicator connection detector 242 determines whether the state of the port replicator connecting signal has been changed. More specifically, if the port replicator connection detector 242 determines based on the result of step S401 that the state of the port replicator connecting signal has been changed by comparing the supply state of the APR connecting signal or the BPR connecting signal with that in the previous port replicator installing/removing detection processing, i.e., if the port replicator connection detector 242 determines that the supply of the APR connecting signal or the BPR connecting signal has started or stopped, the process proceeds to step S403.

In step S403, the port replicator connection detector 242 sets the timer, and the port replicator installing/removing detection processing is completed. If the timer has already been set, the port replicator connection detector 242 resets the timer by setting the timer value to 0.

If it is determined in step S402 that the state of the port replicator connecting signal has not been changed, the process proceeds to step S404.

In step S404, the port replicator connection detector 242 determines whether the timer has been set. If it is determined that the timer has been set, the process proceeds to step S405.

In step S405, the port replicator connection detector 242 updates the timer.

In step S406, the port replicator connection detector 242 determines whether the timer has reached a predetermined time. If the timer has reached the predetermined time, i.e., if the state of the port replicator connecting signal has been changed longer than or equal to the predetermined time (for example, 50 ms) of the timer after it is determined in step S402 in the previous port replicator installing/removing detection processing that the state of the port replicator connecting signal was changed, the process proceeds to step S407. Because of this processing, it is possible to prevent erroneous detection of the connecting state of the APR 112 or the BPR 113 caused by chattering (vibrations of the APR 112 or the BPR 113) when a port replicator is installed or removed to or from the personal computer 111.

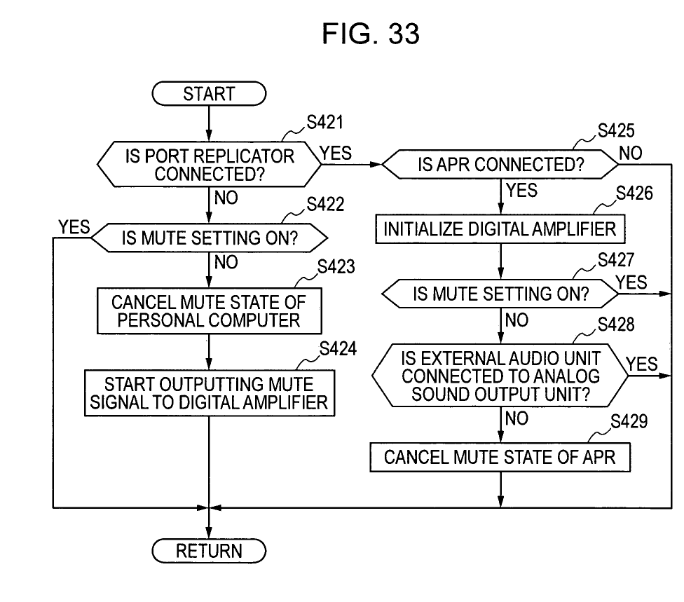

In step S407, the embedded controller 155 executes the port replicator installing/removing processing. By performing this processing, the mute condition of the personal computer 111 or the APR 112 is set, and the digital amplifier 191 of the APR 112 is initialized. Details of the port replicator installing/removing processing are discussed below with reference to FIG. 33.

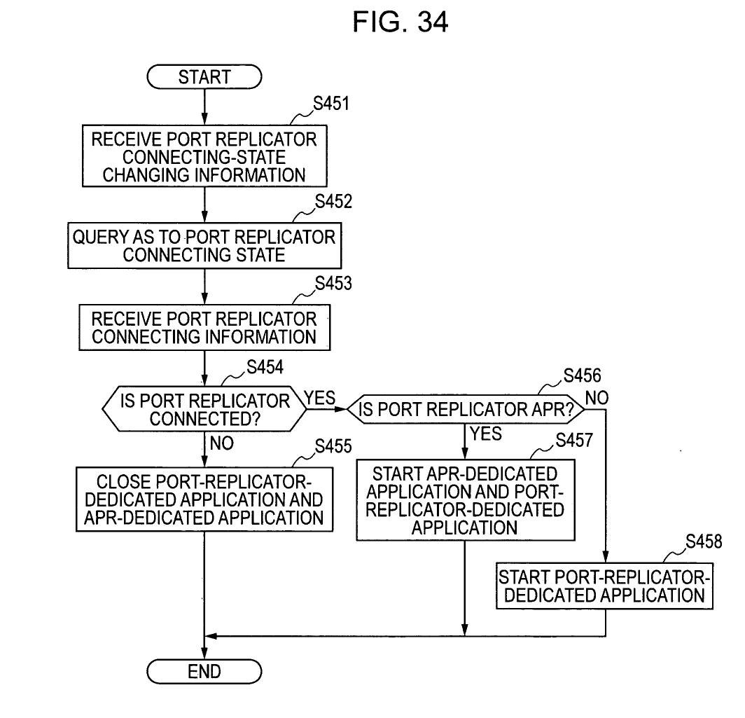

In step S408, the port replicator connection detector 242 informs the utility program 226 that the connecting state of the port replicator has been changed, and the port replicator installing/removing detection processing is then completed. More specifically, the port replicator connection detector 242 supplies port replicator connecting-state changing information to the utility program 226. The utility program 226 receives the port replicator connecting-state changing information in step S451 of FIG. 34, which is discussed below.

If it is determined in step S406 that the timer has not reached the predetermined time, i.e., if the state of the port replicator connecting signal has not been changed longer than or equal to the predetermined time of the timer after it is determined in step S402 in the previous port replicator installing/removing detection processing that the state of the port replicator connecting signal was changed, steps S407 and S708 are skipped, and the port replicator installing/removing detection processing is completed.

If it is determined in step S404 that the timer is not set, steps S405 through S408 are skipped, and the port replicator installing/removing detection processing is completed.

Details of the port replicator installing/removing processing in step S407 of FIG. 32 are described below with reference to the flowchart of FIG. 33.

In step S421, the port replicator connection detector 242 determines whether a port replicator is connected to the personal computer ill. More specifically, the port replicator connection detector 242 determines whether an APR connecting signal or a BPR connecting signal is supplied from the connecting signal output unit 121 of the APR 112 or the connecting signal output unit 131 of the BPR 113, respectively. If it is determined that neither of the APR connecting signal nor the BPR connecting signal is supplied, the port replicator connection detector 242 determines that the port replicator has been removed from the personal computer 111, and the process proceeds to step S422.

In step S422, the mute controller 245 determines whether the mute setting of the information processing system 101 is ON. If it is determined that the mute setting is OFF, i.e., if the mute setting flag is OFF, the process proceeds to step S423.

In step S423, the mute controller 245 cancels the mute state of the personal computer 111.

In step S424, the mute controller 245 starts supplying a mute signal to the digital amplifier 191, and the port replicator installing/removing processing is completed. Actually, however, since the APR 112 is not connected to the personal computer 111, a mute signal is not supplied to the digital amplifier 191 of the APR 112. After this processing, however, when the APR 112 is connected to the personal computer 111, a mute signal is supplied first to the digital amplifier 191 regardless of the mute setting condition of the information processing system 101, and the output of noise from the loudspeaker 192 can be prevented.

If it is determined in step S422 that the mute setting of the information processing system 101 is ON, steps S423 and S424 are skipped, and the port replicator installing/removing processing is completed. That is, the personal computer 111 remains in the mute state.

If it is determined in step S421 that a port replicator is connected, i.e., if an APR connecting signal or a BPR connecting signal is supplied from the connecting signal output unit 121 of the APR 112 or the connecting signal output unit 131 of the BPR 113, respectively, via the hardware signal input unit 241, the process proceeds to step S425.

In step S425, the port replicator connection detector 242 determines whether the APR 112 is connected, as in step S1 of FIG. 8. If it is determined that the APR 112 is connected, the process proceeds to step S426.

In step S426, the digital amplifier controller 247 initializes the digital amplifier 191 of the APR 112. More specifically, the digital amplifier controller 247 supplies digital amplifier initializing data to the digital amplifier 191 to turn ON the digital amplifier initializing flag. The digital amplifier 191 then initializes the internal state or set values of the digital amplifier 191 based on the digital amplifier initializing data.

In step S427, the mute controller 425 determines whether the mute setting of the information processing system 101 is ON, as in step S422. If the mute setting is found to be OFF, the process proceeds to step S428.

In step S428, the mute controller 245 determines whether an external audio unit is connected to the analog sound output unit 163. If an external audio unit is not connected, i.e., an audio-unit connecting signal is not supplied to the mute controller 245 from the analog amplifier 161, the process proceeds to step S429.

In step S429, the mute controller 245 cancels the mute state of the APR 112, and the port replicator installing/removing processing is completed.

If it is determined in step S427 that the mute setting is ON, or if it is determined in step S428 that an external audio unit is connected to the analog sound output unit 163, the port replicator installing/removing processing is terminated. That is, the APR 112 remains in the mute state.

If it is determined in step S425 that the APR 112 is not connected, the sound output state of the personal computer 111 is not changed, and the port replicator installing/removing processing is terminated.

A description is now given, with reference to the flowchart of FIG. 34, of port-replicator-dedicated application control processing by the CPU 151 executing the utility program 226 in association with the port replicator installing/removing detection processing by the embedded controller 155 shown in FIG. 32.

In step S451, the utility program 226 receives the port replicator connecting-state changing information supplied from the port replicator connection detector 242 in step S408 of FIG. 32.

In step S452, the utility program 226 queries the port replicator connection detector 242 as to the port replicator connecting state. More specifically, the utility program 226 supplies port replicator connecting-state query information to the port replicator connection detector 242 via the utility communication unit 246.

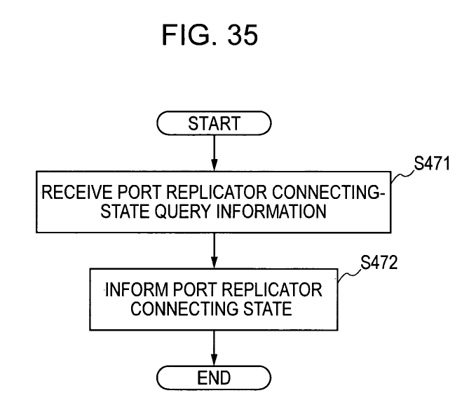

The port replicator connection detector 242 receives the port replicator connecting-state query information in step S471 of FIG. 35, which is discussed below, and supplies port replicator connecting information in step S472.

In step S453, the utility program 226 receives the port replicator connecting information from the port replicator connection detector 242 via the utility communication unit 246.

In step S454, the utility program 226 determines based on the port replicator connecting information whether a port replicator is connected to the personal computer 111. If it is determined that the port replicator is removed, the process proceeds to step S455.

In step S455, the utility program 266 closes the port-replicator-dedicated application, and if the APR 112 is removed, the utility program 266 closes an APR-dedicated application, and the application control processing is completed. The port-replicator-dedicated application is a dedicated application program for using the functions of both the APR 112 and the BPR 113. The APR-dedicated application is an application program for using the functions of only the APR 112, and is, for example, an application program for adjusting the function or the output sound of the digital amplifier 191.

If it is determined in step S454 that a port replicator is connected, the process proceeds to step S456.

In step S456, the utility program 226 determines based on the port replicator connecting information whether the port replicator connected to the personal computer 111 is the APR 112. If the APR 112 is connected, the process proceeds to step S457.

In step S457, the utility program 226 starts the APR-dedicated application and the port-replicator-dedicated application, and the port-replicator-dedicated application control processing is completed. According to this processing, the user can easily use the application program for using the functions of the APR 112 and the application program for using the functions of both the APR 112 and the BPR 113.

If it is determined in step S456 that the port replicator connected to the personal computer 111 is not the APR 112 but the BPR 113, the process proceeds to step S458.

In step S458, the utility program 226 starts the port-replicator-dedicated application, and the port-replicator-dedicated application control processing is completed. According to this processing, the user can easily use the application program for using the functions of both the APR 112 and the BPR 113.

A description is now given, with reference to the flowchart of FIG. 35, of port replicator connecting-state informing processing performed by the embedded controller 155 executing the EC firmware 221 in association with the port-replicator-dedicated application control processing by the utility program 226 shown in FIG. 34.

In step S471, the port replicator connection detector 242 receives the port replicator connecting-state query information supplied from the utility program 226 via the utility communication unit 246 in step S452 of FIG. 34.

In step S472, the port replicator connection detector 242 informs the utility program 226 of the port replicator connecting state, and the port replicator connecting-state informing processing is completed. More specifically, the port replicator connection detector 242 supplies the port replicator connecting information to the utility program 226 via the utility communication unit 246.

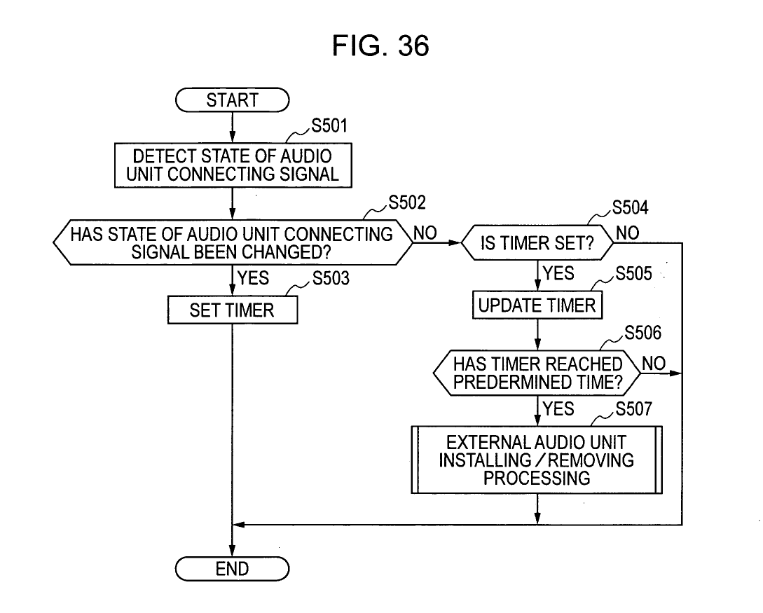

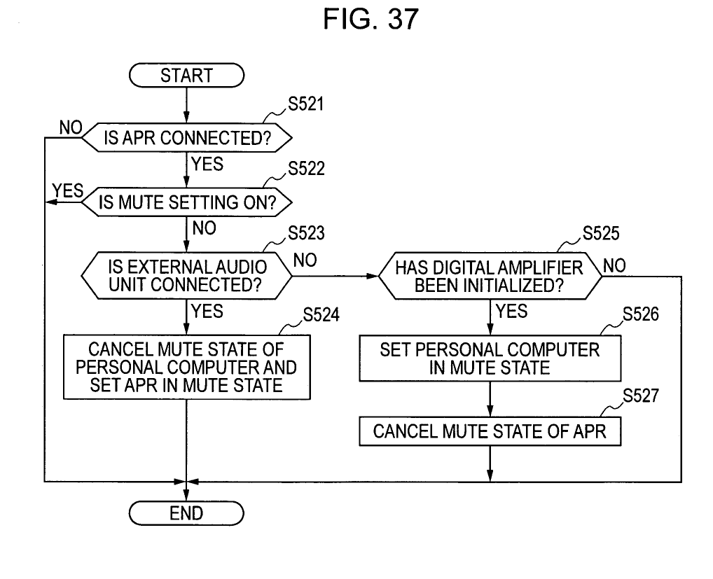

A description is now given, with reference to FIGS. 36 and 37, of mute processing performed by the information processing system 101 when an external audio unit is connected or removed to or from the analog sound output unit 163.

Audio-unit connecting signal polling processing performed by the embedded controller 155 executing the EC firmware 221 is first described with reference to the flowchart of FIG. 36. This processing is executed at regular intervals, for example, 5 ms, when the personal computer 111 is powered ON.

In step S501, the mute controller 245 detects the state of an audio-unit connecting signal. More specifically, if an external audio unit is connected to the analog sound output unit 163, an audio-unit connecting signal is supplied to the mute controller 245 from the analog amplifier 161. The mute controller 245 detects the supply state of the audio-unit connecting state.

In step S502, the mute controller 245 determines whether the state of the audio-unit connecting signal has been changed. More specifically, if the mute controller 245 determines based on the result of step S501 that the state of the audio-unit connecting signal has been changed by comparing the supply state of the audio-unit connecting state with that in the previous audio-unit connecting signal polling processing, i.e., if the mute controller 245 determines that the supply of the audio-unit connecting signal has started or stopped, the process proceeds to step S503.

In step S503, the mute controller 245 sets the timer, and the audio-unit connecting signal polling processing is completed. If the timer has already been set, the mute controller 245 resets the timer by setting the timer value to 0.

If it is determined in step S502 that the state of the audio-unit connecting signal has not been changed, the process proceeds to step S504.

In step S504, the mute controller 245 determines whether the timer is set. If the timer is set, the process proceeds to step S505.

In step S505, the mute controller 245 updates the timer.

In step S506, the mute controller 245 determines whether the timer has reached a predetermined time. If the timer has reached the predetermined time, i.e., if the state of the audio-unit connecting signal has been changed longer than or equal to the predetermined time (for example, 50 ms) of the timer after it is determined in step S502 in the previous audio-unit connecting signal polling processing that the state of the audio-unit connecting signal was changed, the process proceeds to step S507. Because of this processing, it is possible to prevent erroneous detection of the connecting state of an external audio unit caused by chattering (vibrations of the audio unit) when the external audio unit is connected or removed to or from the analog sound output unit 163.

In step S507, the embedded controller 155 executes external audio unit installing/removing processing, and the audio-unit connecting signal polling processing is completed. In the external audio unit installing/removing processing, the mute condition of the personal computer 111 or the APR 112 is set. Details of the external audio unit installing/removing processing are given below with reference to FIG. 37.

If it is determined in step S506 that the timer has not reached the predetermined time, i.e., if it is determined that the state of the audio-unit connecting signal has not been changed longer than or equal to the predetermined time of the timer after it is determined in step S502 in the previous audio-unit connecting signal polling processing that the state of the audio-unit connecting signal was changed, step S507 is skipped, and the audio-unit connecting signal polling processing is completed.

If it is determined in step S504 that the timer is not set, steps S505 through S507 are skipped, and the audio-unit connecting signal polling processing is terminated.

Details of the external audio unit installing/removing processing in step S507 of FIG. 36 are discussed below with reference to the flowchart of FIG. 37.

In step S521, the port replicator connection detector 242 determines whether the APR 112 is connected to the personal computer 111, as in step S1 of FIG. 8. If it is determined that the APR 112 is connected, the process proceeds to step S522.

In step S522, the mute controller 245 determines whether the mute setting of the information processing system 101 is ON. If the mute setting is found to be OFF, the process proceeds to step S523.

In step S523, the mute controller 245 determines whether an external audio unit is connected to the analog sound output unit 163. If it is determined that an external audio unit is connected to the analog sound output unit 163, i.e., that an audio-unit connecting signal is supplied to the mute controller 245 from the analog amplifier 161, the process proceeds to step S524.

In step S524, the mute controller 245 cancels the mute state of the personal computer 111 and sets the APR 112 in the mute state, and the external audio unit installing/removing processing is completed.

If it is determined in step S523 that an external audio unit is not connected, i.e., that an external audio unit is removed from the analog sound output unit 163, the process proceeds to step S525.

In step S525, the digital amplifier controller 247 determines whether the digital amplifier 191 has been initialized, as in step S2 of FIG. 8. If it is determined that the digital amplifier 191 has been initialized, the process proceeds to step S526.

In step S526, the mute controller 245 sets the personal computer 111 in the mute state.

In step S527, the mute controller 245 cancels the mute state of the APR 112, and the external audio unit installing/removing processing is completed.

If it is determined in step S525 that the digital amplifier 191 has not been initialized, steps S526 and S527 are skipped, and the external audio unit installing/removing processing is terminated.

If it is determined in step S521 that the APR 112 is not connected, or if it is determined in step S522 that the mute setting is ON, the sound output state of the personal computer 111 or the APR 112 is not changed, and the external audio unit installing/removing processing is terminated.

If an external audio unit is connected to the analog sound output unit 163, a mute signal may be supplied to the digital amplifier 191 by, for example, hardware processing, in which case, the processing shown in FIGS. 36 and 37 is omitted.

As described above, the volume of the output sound of the loudspeaker 192 of the APR 112 can be set (adjusted) regardless of whether the volume button 157 of the personal computer 111 is operated, the volume switch 193 of the APR 112 is operated, or the system volume setting function of the OS 224 is used. Additionally, the mute setting of the information processing system 101 can be changed regardless of whether the mute button 158 of the personal computer 111 is operated or the mute setting function of the OS 224 is used. In this case, the OS 224 can display mute setting, the LED 159 can be turned ON or OFF, and the display unit 164 can display a dialog in accordance with the actual mute setting.

Since the above-described processing can be executed by the EC firmware 221 or the utility program 226, they can be implemented by changing general-purpose processor firmware, for example, the embedded controller 155, or by installing the utility program 226 into the personal computer 111 without the need to add new components.

As described above, setting data for setting the volume of sound output from a sound output device, the volume being set by a function implemented by a first computer executing a first program, is received. A setting signal for setting the volume of sound output from the sound output device, the volume being supplied from a setting unit provided for the sound output device, is received. Volume control data that controls the volume of sound output from the sound output device is calculated based on the setting data and the setting signal, the volume being controlled by a second computer executing a second program. With this configuration, by outputting the volume control data to the sound output device, the volume of the output sound of a digital sound output device connected to the information processing apparatus can be controlled. Additionally, the volume of the output sound of the digital sound output device can be controlled without the need to add new components.

In the foregoing embodiment, a mobile personal computer is used as an example. In the present invention, however, an electronic device to which a digital sound output unit is connected, for example, an in-vehicle display device or a cellular telephone, may be used.

The above-described series of processing may be executed by hardware or software. If software is used, a corresponding software program may be installed via a network or a recording medium into a computer that is built in dedicated hardware or a general-purpose computer that can implement various functions by installing various programs into the computer.

The recording medium recording therein a program to be installed into a computer and be executed by the computer may be the removable medium 181 distributed, separately from the computer, for providing the program to the user. The removable medium 181 includes a magnetic disk (including a flexible disk), an optical disc (including a compact disc read only memory (CD-ROM) or a digital versatile disc (DVD)), a magneto-optical disk (including mini-disc (MD) (registered)), and a semiconductor memory. Alternatively, the recording medium may be the ROM 152 or a hard disk contained in the recorder 154 recording the program therein, which is provided to the user while being contained in the computer.

In this specification, steps forming the program stored in a program storage medium may be executed in chronological order described in the specification. Alternatively, they may be executed in parallel or individually.

In this specification, the system represents an entire apparatus including a plurality of devices.

It should be understood by those skilled in the art that various modifications, combinations, sub-combinations and alterations may occur depending on design requirements and other factors insofar as they are within the scope of the appended claims or the equivalents thereof.

1. An information processing apparatus to which a sound output device for outputting sound based on digital audio data is connected, comprising:
first receiving means for receiving setting data for setting a volume of sound output from the sound output device, the volume being set by a function implemented by a first computer executing a first program;
second receiving means for receiving a setting signal for setting a volume of sound output from the sound output device, the volume being supplied from setting means provided for the sound output device;
calculation means for calculating first volume control data that controls the volume of sound output from the sound output device based on the setting data and the setting signal, the volume being controlled by a second computer executing a second program; and
first output means for outputting the first volume control data to the sound output device.

2. The information processing apparatus according to claim 1, wherein the calculation means stores in advance first intermediate data corresponding to one of the setting data and the setting signal and converts the one of the setting data and the setting signal into the first intermediate data, thereby calculating the first volume control data based on the other one of the setting data and the setting signal and the first intermediate data.

3. The information processing apparatus according to claim 2, wherein the first volume control data includes second volume control data and third volume control data, and
the calculation means stores in advance the plurality of different second volume control data to which a plurality of different second intermediate data are assigned, the one of the setting data and the setting signal is converted into the first intermediate data, the other one of the setting data and the setting signal and the first intermediate data are added, some bits of a resulting added value are used as the second intermediate data, the remaining bits of the added value are used as the third volume control data, and the second intermediate data is converted into the second volume control data to which the second intermediate data is assigned, thereby calculating the first volume control data.

4. The information processing apparatus according to claim 1, wherein the second receiving means receives a stop instruction signal indicating an instruction to stop outputting the sound from the sound output device, the information processing apparatus further comprising:
second output means for outputting, in response to the stop instruction signal, a mute signal indicating an instruction to stop outputting the sound from the sound output device to the sound output device and also for outputting mute changing information indicating a change in the output of the mute signal to the first computer executing the first program.

5. A volume control method for an information processing apparatus to which a sound output device for outputting sound based on digital audio data is connected, the volume control method comprising the steps of:
performing a first receiving operation for receiving setting data for setting a volume of sound output from the sound output device, the volume being set by a function implemented by a first computer executing a first program;
performing a second receiving operation for receiving a setting signal for setting a volume of sound output from the sound output device, the volume being supplied from setting means provided for the sound output device;
calculating volume control data that controls the volume of sound output from the sound output device based on the setting data and the setting signal, the volume being controlled by a second computer executing a second program; and
outputting the volume control data to the sound output device.

6. A recording medium recording therein a computer-readable program, the computer-readable program being used for controlling a volume of a second computer of an information processing apparatus, a sound output device for outputting sound based on digital audio data being connected to the information processing apparatus, the information processing apparatus including receiving means for receiving setting data for setting a volume of sound output from the sound output device, the volume being set by a function implemented by a first computer executing a volume setting program, the computer-readable program comprising the steps of:
receiving a setting signal for setting a volume of sound output from the sound output device, the volume being supplied from setting means provided for the sound output device;
calculating volume control data that controls the volume of sound output from the sound output device based on the setting data and the setting signal; and
outputting the volume control data to the sound output device.

7. A program allowing a second computer of an information processing apparatus to execute volume control processing for controlling a volume of the information processing apparatus, a sound output device for outputting sound based on digital audio data being connected to the information processing apparatus, the information processing apparatus including receiving means for receiving setting data for setting a volume of sound output from the sound output device, the volume being set by a function implemented by a first computer executing a volume setting program, the program comprising the steps of:
receiving a setting signal for setting a volume of sound output from the sound output device, the volume being supplied from setting means provided for the sound output device;
calculating volume control data that controls the volume of sound output from the sound output device based on the setting data and the setting signal; and
outputting the volume control data to the sound output device.

8. An information processing apparatus to which a sound output device for outputting sound based on digital audio data is connected, comprising:
a first receiver receiving setting data for setting a volume of sound output from the sound output device, the volume being set by a function implemented by a first computer executing a first program;
a second receiver receiving a setting signal for setting a volume of sound output from the sound output device, the volume being supplied from a setting unit provided for the sound output device;
a calculator calculating first volume control data that controls the volume of sound output from the sound output device based on the setting data and the setting signal, the volume being controlled by a second computer executing a second program; and
a first output unit outputting the first volume control data to the sound output device.
